(19) United States
(12) Patent Application Publication
(10) Pub. No.: US 2020/0091015 A1
(43) Pub. Date: Mar. 19, 2020

(54) SUBSTRATE BONDING METHOD, MULTILAYER SUBSTRATE MANUFACTURING METHOD, MULTILAYER SUBSTRATE MANUFACTURING APPARATUS, AND MULTILAYER SUBSTRATE MANUFACTURING SYSTEM

(71) Applicant: NIKON CORPORATION, TOKYO (JP)

(72) Inventors: Isao SUGAYA, Tokyo (JP); Hajime MITSUISHI, Tokyo (JP)

(73) Assignee: NIKON CORPORATION, TOKYO (JP)

(21) Appl. No.: 16/698,238

(22) Filed: Nov. 27, 2019

Related U.S. Application Data
(63) Continuation of application No. PCT/JP2018/020075, filed on May 24, 2018.

(30) Foreign Application Priority Data
May 29, 2017 (JP) 2017-106054

(51) Int. Cl. H01L 21/66; H01L 23/00; H01L 21/687; H01L 21/68; H01L 21/67

(52) U.S. Cl. CPC H01L 22/12; H01L 24/74; H01L 24/89; H01L 21/68735; H01L 2924/3511; H01L 21/67288; H01L 21/67253; H01L 21/67259; H01L 21/681

(57) ABSTRACT

When distortion occurs in substrates before bonding, this distortion dissipates when the hold on the substrate by a holding section is released, and misalignment occurs between the two bonded substrates. Provided is a substrate bonding method for bonding a first substrate held by a first holding section and a second substrate held by a second holding section, by releasing the hold on at least one of the first substrate and the second substrate, the substrate bonding method including determining which of the first substrate and the second substrate is to be released from the hold or continued to be held, based on information concerning distortion of at least one of the first substrate and the second substrate, wherein the information concerning the distortion includes information concerning distortion occurring in a bonding process of the first substrate and the second substrate.

The contents of the following Japanese and international patent applications are incorporated herein by reference:
2017-106054 filed in JP on May 29, 2017, and
PCT/JP2018/020075 filed on May 24, 2018

### BACKGROUND

### 1. Technical Field

The present invention relates to a substrate bonding method, a multilayer substrate manufacturing method, a multilayer substrate manufacturing apparatus, and a multilayer substrate manufacturing system.

### 2. Related Art

A method is known in which substrates held respectively by two opposing holding sections are positionally aligned with each other, and then these two substrates are bonded by releasing the hold on one of the substrates, as shown in Patent Document 1, for example.
Patent Document 1: Japanese Patent Application Publication No. 2015-95579

With this method, since the hold on one of the substrates is released by the holding section when the substrates are bonded, there are cases where distortion of the one substrate is eliminated due to the release of the holding or distortion is caused by the external force applied during the bonding process. When positional misalignment occurs between the two substrates to be bonded due to this distortion, it becomes impossible to suitably bond the two substrates.

### SUMMARY

According to a first aspect of the present invention, provided is a substrate bonding method for bonding a first substrate held by a first holding section and a second substrate held by a second holding section, by releasing the hold on at least one of the first substrate and the second substrate, the substrate bonding method comprising determining which of the first substrate and the second substrate is to be released from the hold or continued to be held, based on information concerning distortion of at least one of the first substrate and the second substrate, wherein the information concerning the distortion includes information concerning distortion occurring in a bonding process of the first substrate and the second substrate.

According to a second aspect of the present invention, provided is a substrate bonding method comprising holding a first substrate with a first holding section; holding a second substrate with a second holding section in a manner to face the first substrate; and bonding the first substrate and the second substrate by releasing the hold on one of the first substrate and the second substrate, wherein the bonding includes releasing the hold on a substrate, among the first substrate and the second substrate, in which distortion occurring in a bonding process satisfies a prescribed condition.

According to a third aspect of the present invention, provided is a substrate bonding method for bonding a first substrate held by a first holding section and a second substrate held by a second holding section, by releasing the hold on at least one of the first substrate and the second substrate, the substrate bonding method comprising determining which of the first substrate and the second substrate is to be held by the first holding section or by the second holding section, based on information concerning distortion occurring in a bonding process of the first substrate and the second substrate.

According to a fourth aspect of the present invention, provided is a substrate bonding method for bonding a first substrate held by a first holding section and a second substrate held by a second holding section, by releasing the hold on one of the first substrate and the second substrate, the substrate bonding method comprising determining which of the first substrate and the second substrate is to be released from the hold or continued to be held, based on information concerning distortion of at least one of the first substrate and the second substrate.

According to a fifth aspect of the present invention, provided is a substrate bonding method for bonding a first substrate held by a first holding section and a second substrate held by a second holding section, by releasing the hold on one of the first substrate and the second substrate, wherein a substrate, among the first substrate and the second substrate, causing positional misalignment after bonding that is less than or equal to a threshold value is released from the hold.

According to a sixth aspect of the present invention, provided is a substrate bonding method comprising holding a first substrate with a first holding section; holding a second substrate with a second holding section; correcting positional misalignment between the first substrate and the second substrate; and bonding the first substrate and the second substrate by releasing the hold on one of the first substrate and the second substrate, wherein a substrate, among the first substrate and the second substrate, causing a correction amount for positional misalignment predicted for after the bonding with a magnitude capable of being corrected by the correcting is released from the hold.

According to a seventh aspect of the present invention, provided is a multilayer substrate manufacturing method comprising bonding a first substrate held by a first holding section and a second substrate held by a second holding section, by releasing the hold on at least one of the first substrate and the second substrate; and determining which of the first substrate and the second substrate is to be released from the hold or continued to be held, based on information concerning distortion occurring in the bonding of the first substrate and the second substrate, wherein the bonding includes releasing the hold on the substrate that was determined to be released in the determining.

According to an eighth aspect of the present invention, provided is a multilayer substrate manufacturing apparatus comprising a first holding section holding a first substrate; and a second holding section holding a second substrate, wherein the multilayer substrate manufacturing apparatus manufactures a multilayer substrate by bonding the first substrate and the second substrate, by releasing the hold on one of the first substrate and the second substrate, and a substrate, among the first substrate and the second substrate, causing positional misalignment after bonding that is less than or equal to a threshold value is released from the hold

According to a ninth aspect of the present invention, provided is a multilayer substrate manufacturing apparatus, comprising a first holding section that holds a first substrate; and a second holding section that holds a second substrate in a manner to face the first substrate, wherein the multilayer substrate manufacturing apparatus manufactures a multilayer substrate by bonding the first substrate and the second substrate, by releasing the hold on one of the first substrate and the second substrate, and a substrate, among the first substrate and the second substrate, in which distortion occurring in a bonding process satisfies a prescribed condition is released from the hold.

According to a tenth aspect of the present invention, provided is a multilayer substrate manufacturing apparatus, comprising a first holding section that holds a first substrate; a second holding section that holds a second substrate in a manner to face the first substrate; and a correcting section that corrects positional misalignment between the first substrate and the second substrate, wherein the multilayer substrate manufacturing apparatus manufactures a multilayer substrate by bonding the first substrate and the second substrate, by releasing the hold on one of the first substrate and the second substrate, and a substrate, among the first substrate and the second substrate, causing a correction amount for positional misalignment predicted for after the bonding with a magnitude capable of being corrected by the correcting section is released from the hold.

According to an eleventh aspect of the present invention, provided is a multilayer substrate manufacturing system comprising a bonding section that includes a first holding section holding a first substrate and a second holding section holding a second substrate, and bonds the first substrate and the second substrate by releasing the hold on one of the first substrate and the second substrate; and a determining section that determines which of the first substrate and the second substrate is to be released from the hold or continued to be held, based on information concerning distortion occurring during a bonding process of the first substrate and the second substrate, wherein the bonding section releases the hold on the substrate determined to be released by the determining section.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic planar view of a multilayer substrate manufacturing apparatus 100.

FIG. 2 is a schematic planar view of a substrate 210 to be bonded.

FIG. 3 is a flow chart showing a procedure for manufacturing a multilayer substrate 230 by layering a pair of substrates 210.

FIG. 4 is a schematic cross-sectional view of the substrate holder 221 holding the substrate 211 and the substrate holder 223 holding the substrate 213.

FIG. 5 is a schematic cross-sectional view of the bonding section 300.

FIG. 6 is a schematic cross-sectional view of the bonding section 300.

FIG. 7 is a schematic cross-sectional view of the bonding section 300.

FIG. 8 is a schematic cross-sectional view of the bonding section 300.

FIG. 9 is a schematic cross-sectional view of the bonding section 300.

FIG. 10 is a partial enlarged view showing the bonding process of the substrates 211 and 213 on the substrate holder 221 for the fixed side that has a flat holding surface.

FIG. 11 is a partial enlarged view showing the bonding process of the substrates 211 and 213 on the substrate holder 221 for the fixed side that has a flat holding surface.

FIG. 12 is a partial enlarged view showing the bonding process of the substrates 211 and 213 on the substrate holder 221 for the fixed side that has a flat holding surface.

FIG. 13 is a schematic view of the positional misalignment on the multilayer substrate 230 due to by the scaling distortion caused by air resistance occurring when the substrate holder 221 used for the fixed side has a flat holding surface.

FIG. 14 is a partial enlarged view of the bonding process of the substrates 211 and 213 on a substrate holder 221, in a case where the scaling distortion caused by air resistance has been corrected using the substrate holder 221 for the fixing side that has a curved holding surface.

FIG. 15 is a schematic view of a relationship between the crystal anisotropy and Young's modulus in a silicon single-crystal substrate 208.

FIG. 16 is a schematic view of a relationship between the crystal anisotropy and Young's modulus in a silicon single-crystal substrate 209.

FIG. 17 is a schematic view of positional misalignment in the multilayer substrate 230 caused by non-linear distortion occurring when the substrate 210 on the releasing side is partially curved.

FIG. 18 is a diagram for describing the deflection measurement and warping calculation method.

FIG. 19 is a schematic view of substrates 511 and 513 having a plurality of circuit regions 216 formed on the surfaces thereof with an arrangement corrected in advance, such that the amount of positional misalignment in the multilayer substrate 230 due to the scaling distortion caused by air resistance that can occur during bonding and the non-linear distortion caused by crystal anisotropy becomes less than or equal to a predetermined threshold value.

FIG. 20 is a flow chart showing a procedure for bonding the substrates 511 and 513 shown in FIG. 19 that have been corrected in advance.

FIG. 21 is a diagram describing a method for correcting the scaling distortion caused by air resistance that can occur during bonding, in a case where, in a manner opposite the tentative determination described above, a determination is made to set the substrate 511 shown in FIG. 19 on the releasing side.

FIG. 22 is a schematic cross-sectional view of a portion of the bonding section 600 according to another embodiment.

FIG. 23 is a schematic view of a layout of the actuators 612.

FIG. 24 is a schematic view of the operation of a portion of the bonding section 600.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

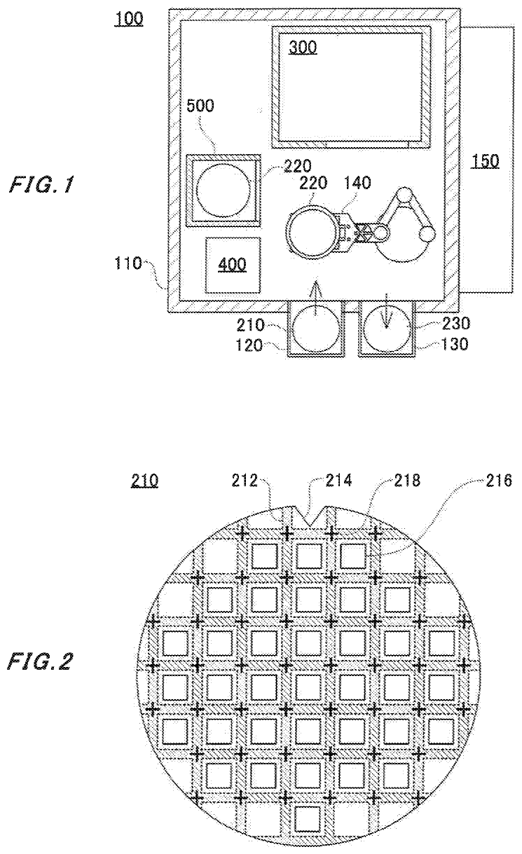

FIG. 1 is a schematic planar view of a multilayer substrate manufacturing apparatus 100. The multilayer substrate manufacturing apparatus 100 includes a case 110, a substrate cassette 120 that houses substrates 210 to be bonded, a substrate cassette 130 that houses multilayer substrates 230 manufactured by bonding at least two substrates 210, a control section 150, a transporting section 140, a bonding section 300, a holder stocker 400 that houses substrate holders 220 that hold the substrates 210, and a pre-aligner 500. The inside of the case 110 is temperature controlled to be kept at room temperature, for example.

The transporting section 140 transports a single substrate 210, a substrate holder 220, a substrate holder 220 holding a substrate 210, a multilayer substrate 230 formed by layering a plurality of substrates 210, or the like. The control section 150 performs overall control of each section of the multilayer substrate manufacturing apparatus 100 by being linked to these sections. Furthermore, the control section 150 receives user instructions from the outside to set manufacturing conditions for manufacturing the multilayer substrates 230. Yet further, the control section 150 includes a user interface that displays the operating state of the multilayer substrate manufacturing apparatus 100 to the outside.

The bonding section 300 includes a pair of opposing stages 322 and 332. Substrates 210 are held respectively by the pair of stages 322 and 332 via substrate holders 220. After positionally aligning a pair of substrates 210 held by the pair of stages 322 and 332 with each other, the bonding section 300 keeps one of the substrates 210 in the pair in a state of being held to the corresponding stage while the other substrate 210 in the pair is released from the other stage facing the one substrate 210, thereby forming the multilayer substrate 230 by causing the pair of substrates 210 to contact each other and be bonded. In this bonding method, the substrate 210 that is kept in the state of being held by the one stage is referred to as the substrate 210 on the fixed side, and the substrate 210 that is released from being held by the other stage when the bonding is performed is referred to as the substrate 210 on the releasing side.

Here, the bonded state includes a state in which terminals provided to the two substrates layered on each other are connected to each other, thereby ensuring electrical conduction between the two substrates or causing the bonding strength between the two substrates to be greater than or equal to a prescribed strength. Furthermore, the bonded state includes a state in which two substrates are temporarily bonded before processing such as annealing, i.e. a state in which the substrates are tentatively bonded, such that the two substrate are ultimately electrically connected or where the bonding strength between the two substrates is greater than or equal to a prescribed strength due to performing a process such as annealing on the two layered substrates. The state in which the bonding strength is greater than or equal to a prescribed strength due to annealing includes a state in which surfaces of the two substrates are bonded to each other by a shared bond, for example. Furthermore, the state of being tentatively bonded includes a state in which two stacked substrates can be separated from each other and reused.

The pre-aligner 500 positionally aligns each substrate 210 with a substrate holder 220 and causes the substrate holder 220 to hold the substrate 210. The substrate holder 220 is formed by a hard material such as alumina ceramic, and holds the substrate 210 by adhering the substrate 210 thereto using an electrostatic chuck, vacuum chuck, or the like.

In the multilayer substrate manufacturing apparatus 100 such as described above, in addition to bonding substrates 210 having elements, circuits, terminals, and the like formed thereon, it is also possible to bond unprocessed silicon wafers, SiGe substrates with added Ge, Ge single crystal substrates, group III-V or II-VI compound semiconductor wafers, glass substrates, and the like. The bonding targets may be a circuit substrate and an unprocessed substrate, or may be two unprocessed substrates. Each substrate 210 to be bonded may be the substrate 210 itself, of may be a multilayer substrate 230 that includes a plurality of substrates that are already layered.

FIG. 2 is a schematic planar view of a substrate 210 to be bonded by the multilayer substrate manufacturing apparatus 100. The substrate 210 includes a notch 214, a plurality of circuit regions 216, and a plurality of alignment marks 218.

The plurality of circuit regions 216 are an example of structures formed on the surface of the substrate 210, and are arranged periodically along the surface of the substrate 210. Each of the plurality of circuit regions 216 is provided with structures such as a protective film and a wire formed by photolithography techniques or the like. Connecting sections such as pads or bumps that serve as connection terminals when the substrate 210 is connected to another substrate 210, a lead frame, or the like are arranged on the plurality of circuit regions 216. The connecting sections are also an example of structures formed on the surface of the substrate 210.

The plurality of alignment marks 218 are also an example of a structure formed on the surface of the substrate 210, and are arranged in scribe lines 212 that are arranged between the plurality of circuit regions 216. The plurality of alignment marks 218 are indicators used when positionally aligning the substrate 210 with another substrate 210.

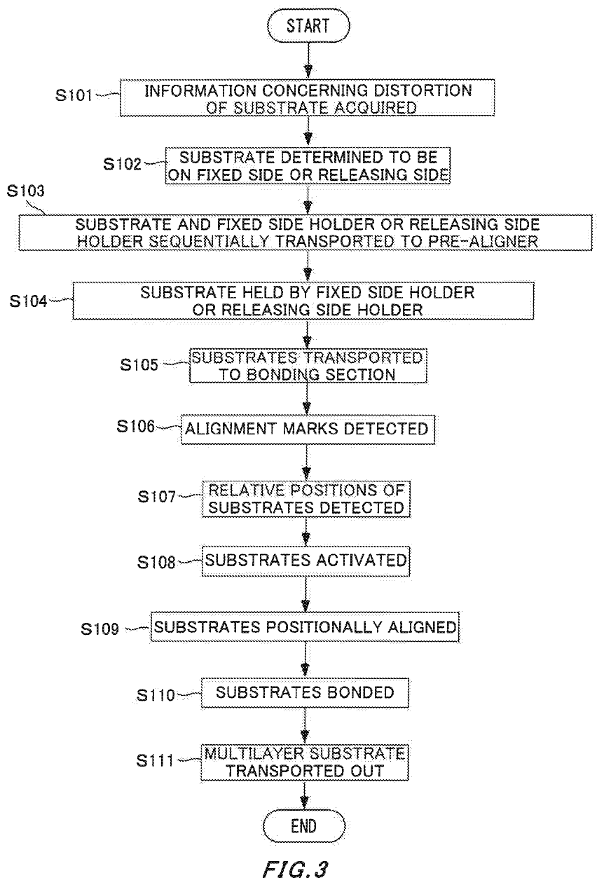

FIG. 3 is a flow chart showing a procedure for manufacturing a multilayer substrate 230 by layering a pair of substrates 210 using the multilayer substrate manufacturing apparatus 100. First, the control section 150 acquires information relating to distortion of each of the substrates 211 and 213 to be bonded (step S101), and then determines which of the substrates 211 and 213 is to be the on the fixed-side stage and which is to be on the releasing-side stage among the pair of stages of the bonding section 300, based on the acquired information (step S102). In other words, in the present embodiment, the control section 150 serves as the determining section. Here, the substrate 211 is determined to be on the fixed side and the substrate 213 is determined to be on the releasing side. At this time, the control section 150 may determine only one of the substrate to be on the fixed side and the substrate to be on the releasing side among the two substrates 211 and 213. The substrate 211 and the substrate 213 are each an example of a substrate 210.

Next, based on the output from the control section 150, the transporting section 140 sequentially transports the substrate holder 221 for the fixed side and the substrate 211 determined to be on the fixed side to a pre-aligner 500 (step S103). In the pre-aligner 500, the substrate 211 is held by the substrate holder 221 for the fixed side (step S104). For the substrate 213, in the same manner as the substrate 211, the transporting section 140 sequentially transports the substrate holder 223 for the releasing side and the substrate 213 determined to be for the releasing side to the pre-aligner 500, based on the output from the control section 150 (step S103), and the substrate 213 is held by the substrate holder 223 for the releasing side in the pre-aligner 500 (step S104). The substrate holder 221 and the substrate holder 223 are each an example of a substrate holder 220.

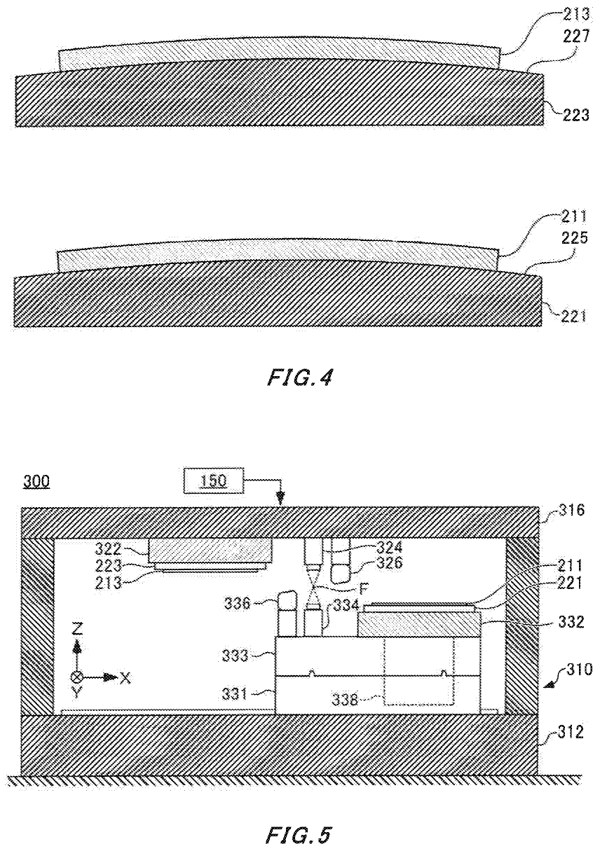

FIG. 4 is a schematic cross-sectional view of the substrate holder 221 holding the substrate 211 and the substrate holder 223 holding the substrate 213. The substrate holder 221 has a cross-sectional shape with a thickness that gradually increases from the peripheral edge to the center. Therefore, the substrate holder 221 has a curved and smooth holding surface 225. The substrate 211 held by being adhered to the substrate holder 221 is firmly held on the holding surface 225 in a manner to curve in accordance with the shape of the holding surface 225. Accordingly, in a case where the curved surface of the holding surface is a cylindrical surface, spherical surface, parabolic surface, or the like, for example, the substrate 213 adhered thereto has its shape changed to become such a curved surface. In the same manner as the substrate holder 221, the substrate holder 223 has a cross-sectional shape with a thickness that gradually increases from the peripheral edge to the center, and therefore the substrate holder 223 has a curved and smooth holding surface 227. The substrate 213 held by being adhered to the substrate holder 223 is firmly held on the holding surface 227 in a manner to curve in accordance with the shape of the holding surface 227.

In FIG. 4, the holding surface 225 of the substrate holder 221 and the holding surface 227 of the substrate holder 223 are each shown having substantially the same curvature and shape, but the present embodiment is not limited to this. The curvature and shape of the holding surface 227 of the substrate holder 223 for the releasing side may be designed in a manner to cause the substrates to first contact each other at portions thereof, such that a void is not created between the substrate 211 and the substrate 213 bonded by the bonding section 300. On the other hand, the curvature and shape of the holding surface 225 of the substrate holder 221 for the fixed side may be designed in a manner to correct distortion caused by air resistance or the like that can occur when the substrate 211 and the substrate 213 are bonded. Accordingly, the curvatures and shapes of the respective holding surfaces may be the same as or different from each other, in order to individually design each holding surface for a different purpose.

Furthermore, the holding surfaces 225 and 227 of the respective substrate holders 221 and 223 may have any shape, as long as the purposes are fulfilled by each holding surface. For example, by causing the shape of a holding surface of the lower stage 332 to protrude gently upward, instead of forming the holding surface 225 of the substrate holder 221 for the fixed side to be flat, the substrate holder 221 and the substrate 211 may be deformed. Yet further, the holding surface 227 of the substrate holder 223 on the releasing side may be formed to have a shape in which the peripheral edge region is flat and the center region protrudes, and this protrusion amount may be variable. If the holding surface 225 of the substrate holder 221 on the fixed side has a curved shape, the holding surface 227 of the substrate holder 223 on the releasing side may be flat.

As shown in FIG. 5, the substrate holder 221 holding the substrate 211 is transported to the lower stage 332 of the bonding section 300, and the substrate holder 223 holding the substrate 213 is transported to the upper stage 322 of the bonding section 300 (step S105). The upper stage 322 has a holding function realized by a vacuum chuck, electrostatic chuck, or the like, and is fixed to the ceiling plate 316 of the frame 310 while facing downward. The lower stage 332 has a holding function realized by a vacuum chuck, electrostatic chuck, or the like, and is mounted on the top surface of a Y-direction drive section 333 stacked on an X-direction drive section 331 that is arranged on the floor plate 312 of the frame 310. In each of FIGS. 5 to 9, in order to simplify the description, the holding surface 225 of the substrate holder 221 and the holding surface 227 of the substrate holder 223 are both shown to be flat.

A microscope 324 and an activation apparatus 326 are fixed to the ceiling plate 316, at a side of the upper stage 322. The microscope 324 can monitor the top surface of the substrate 211 held on the lower stage 332. The activation apparatus 326 generates plasma for cleaning the top surface of the substrate 211 held on the lower stage 332.

The X-direction drive section 331 moves parallel to the floor plate 312, in a direction indicated by the arrow X in the drawing. The Y-direction drive section 333 moves parallel to the floor plate 312, on top of the X-direction drive section 331, in a direction indicated by the arrow Y in the drawings. By combining the motion of the X-direction drive section 331 and the motion of the Y-direction drive section 333, the lower stage 332 is moved two-dimensionally and parallel to the floor plate 312.

Furthermore, the lower stage 332 is supported by the raising and lowering drive section 338 and is raised and lowered in a direction indicated by the arrow Z due to the driving of the raising and lowering drive section 338.

The movement amount of the lower stage 332 caused by the X-direction drive section 331, the Y-direction drive section 333, and the raising and lowering drive section 338 is measured precisely using an interferometer or the like.

A microscope 334 and an activation apparatus 336 are each mounted on the Y-direction drive section 333, below the lower stage 332. The microscope 334 can monitor the bottom surface, which is the front surface, of the substrate 213 held by the upper stage 322. The activation apparatus 336 generates plasma for cleaning the front surface of the substrate 213. The activation apparatuses 326 and 336 may be provided in an apparatus that is separate from the bonding section 300, and substrates that have already had their surfaces activated and substrate holders may be transported to the bonding section 300 from the activation apparatuses 326 and 336 by a robot.

The bonding section 300 may further include a rotational driving section that causes the lower stage 332 to rotate on a rotational axis that is perpendicular to the floor plate 312 and a swinging driving section that causes the lower stage 332 to swing. In this way, it is possible to move the lower stage 332 parallel to the upper stage 322, and also to rotate the substrate 211 held on the lower stage 332 to improve the positional alignment accuracy of the substrates 211 and 213.

The microscopes 324 and 334 are calibrated by the control section 150, by matching the focal points thereof and monitoring shared indicators. In this way, the relative positions of the microscopes 324 and 334 forming a pair are measured in the bonding section 300.

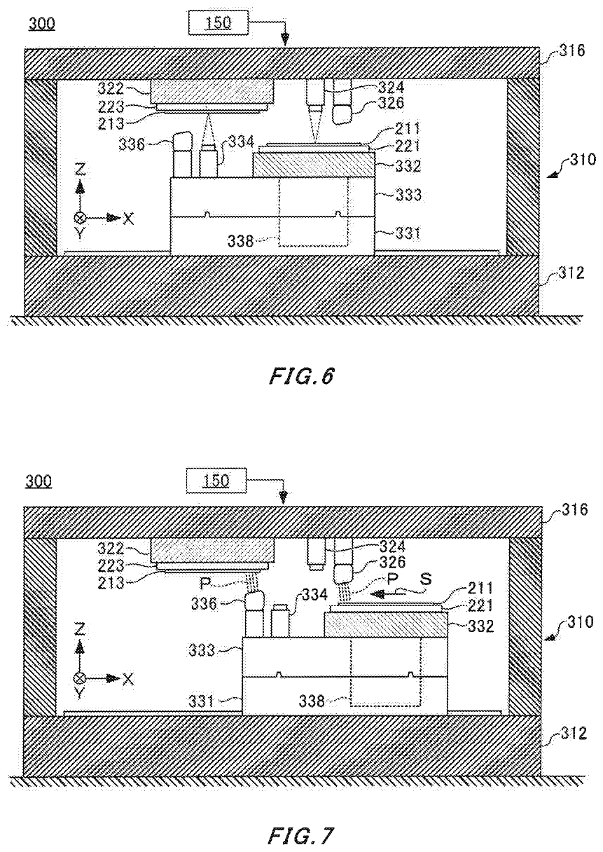

Following the state shown in FIG. 5, as shown in FIG. 6, the control section 150 causes the X-direction drive section 331 and the Y-direction drive section 333 to operate to detect alignment marks 218 provided respectively to the substrates 211 and 213 using the microscopes 324 and 334 (step S106 in FIG. 3).

In this way, by detecting the positions of the alignment marks 218 of the substrates 211 and 213 with the microscopes 324 and 334 whose relative positions are known, the relative positions of the substrates 211 and 213 are determined (step S107). In this way, the relative movement amounts of the substrates 211 and 213 are calculated such that a positional misalignment amount between corresponding alignment marks 218 of the pair of substrates 211 and 213 becomes less than or equal to a predetermined threshold value or such that a positional misalignment amount between corresponding circuit regions 216 or connecting sections of the substrates 211 and 213 becomes less than or equal to a predetermined value. The positional misalignment refers to the positional misalignment between corresponding alignment marks 218 and the positional misalignment between corresponding connecting sections of the layered substrates 211 and 213, and includes positional misalignment caused by different amounts of distortion occurring between the two substrates 211 and 213. This distortion is described further below.

The threshold value referred to above may be an amount of misalignment at which it is still possible for electrical conduction to occur between the substrates 211 and 213 when the bonding of these substrates 211 and 213 to each other has been completed, or may be the amount of misalignment at the time when at least portions of the structures provided respectively to the substrates 211 and 213 contact each other. If the positional misalignment between the substrates 211 and 213 is greater than or equal to the threshold value, the control section 150 may determine that the current state is such that the connecting portions are not in contact with each other or suitable electrical conduction cannot be realized, or that the current state is such that the prescribed bonding strength cannot be realized between the bonded portions. Furthermore, in a case where the distortion caused by the process of bonding the substrates 211 and 213 is dealt with in advance before the bonding, i.e. a case where at least one of the substrates 211 and 213 is deformed before the bonding in order to correct the positional misalignment caused by distortion occurring when the bonding has been completed, the threshold value is set based on the position of the one substrate that is in the deformed state before the bonding.

Following the state shown in FIG. 6, as shown in FIG. 7, the control section 150 records the relative positions of the substrates 211 and 213 forming a pair, and chemically activates the respective bonding surfaces of the substrates 211 and 213 in the pair (step S108 of FIG. 3). First, the control section 150 resets the lower stage 332 to be at the initial position, and then moves the lower stage 332 horizontally to cause the plasma generated by the activation apparatuses 326 and 336 to travel across the surfaces of the substrates 211 and 213. In this way, the respective surfaces of the substrates 211 and 213 are cleaned to increase the chemical reactivity thereof.

The surfaces of the substrates 211 and 213 can be activated using a method other than plasma exposure, such as sputter etching using an inert gas, using an ion beam, or using a fast atomic beam. If an ion beam or a high-speed particle beam is used, it is possible to generate these beams in the bonding section 300 having reduced pressure. Furthermore, it is possible to activate the substrates 211 and 213 using ultraviolet irradiation, an ozone asher, or the like. Yet further, the surfaces of the substrates 211 and 213 may be activated by chemical cleaning using a liquid or gas etchant, for example. After the surfaces of the substrates 211 and 213 have been activated, the surfaces of the substrates 211 and 213 may be hydrophilized by a hydrophilizing apparatus.

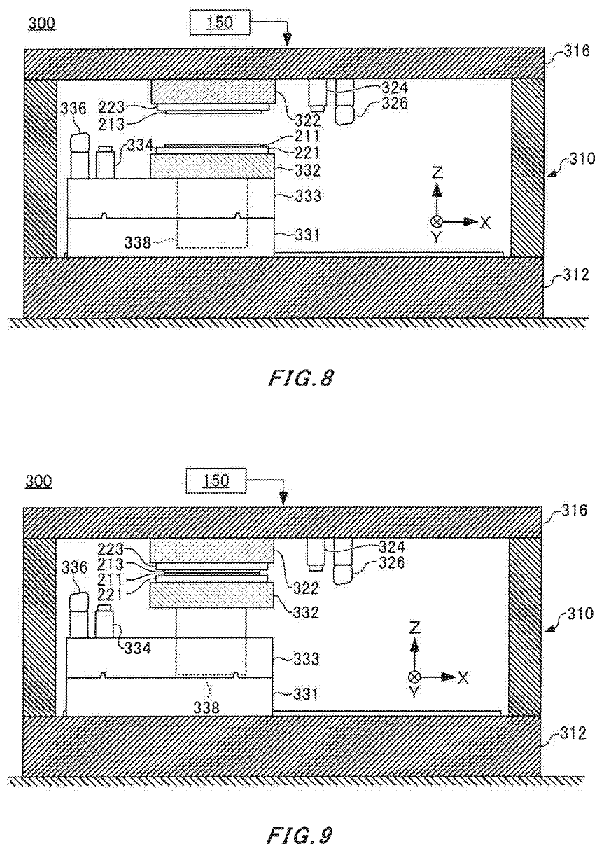

Following the state shown in FIG. 7, as shown in FIG. 8, the control section 150 positionally aligns the substrates 211 and 213 with each other (step S109 of FIG. 3). First, the control section 150 moves the lower stage 332 such that the positional misalignment amount of structures of the substrates 211 and 213 that correspond to each other becomes less than or equal to the threshold value at least when the bonding has been completed, based on the relative positions of the microscopes 324 and 334 detected first and the positions of the alignment marks 218 of the substrates 211 and 213 detected at step S106.

Following the state shown in FIG. 8, as shown in FIG. 9, the control section 150 causes the raising and lowering drive section 338 to operate to raise the lower stage 332, thereby causing the substrates 211 and 213 to move closer to each other. Then, portions of the substrates 211 and 213 contact each other and are bonded (step S110).

Since the surfaces of the substrates 211 and 213 are activated, when these portions contact each other, adjacent regions are autonomously adhered and bonded to each other due to the intermolecular force between the substrates 211 and 213. Accordingly, by releasing the hold on the substrate 213 by the substrate holder 223 that is held by the upper stage 322, for example, the region where the substrates 211 and 213 are bonded sequentially expands from the contact region to adjacent regions. As a result, a bonding wave occurs in which the contact region sequentially expands, and the bonding between the substrates 211 and 213 progresses. Finally, the entire surface of the substrate 211 is in contact with the entire surface of the substrate 213, and these substrates 211 and 213 are bonded together (step S110). In this way, the multilayer substrate 230 is formed from the pair of substrates 211 and 213.

During the step in which the contact region between the substrates 211 and 213 expands in the manner described above, the control section 150 may release the hold on the substrate holder 223 by the upper stage 322 instead of releasing the hold on the substrate 213 by the substrate holder 223.

The multilayer substrate 230 formed in this way is transported out from the bonding section 300 together with the substrate holder 221 by the transporting section 140 (step S111). After this, the multilayer substrate 230 and the substrate holder 221 are separated from each other by the pre-aligner 500, and the multilayer substrate 230 is transported to the substrate cassette 130.

When distortion occurs in the substrate 210 before the bonding, this causes positional misalignment to occur when the bonding is performed. In this case, even though the substrates 211 and 213 are aligned in the surface direction by the bonding section 300 based on the alignment marks 218 and the like, there are cases where the relative movement amount and relative rotation amount that cause the positional misalignment between the substrates 211 and 213 to become less than or equal to the threshold value cannot be calculated, and the positional misalignment between the substrates 211 and 213 cannot be eliminated. Therefore, at step S101 and step S102 shown in FIG. 3, the control section 150 acquires information concerning the distortion of each of the substrates 211 and 213 that are to be bonded, and based on the acquired information, fixes one of the substrates 211 and 213 to the lower stage 332 of the bonding section 300 or determines one of the substrates 211 and 213 to be released from the upper stage 322 of the bonding section 300.

Here, the distortion occurring in the substrates 211 and 213 is deformation causing the positions of structures on the substrates 211 and 213 to be displaced from the design coordinates, i.e. the design positions. The distortion occurring in the substrates 211 and 213 includes planar distortion and stereoscopic distortion.

The planar distortion is distortion occurring along the bonding surfaces of the substrates 211 and 213, and includes linear distortion in which the position of each structure of the substrates 211 and 213 is displaced relative to the design position of the structure is represented by a linear transformation, and non-linear distortion that is not linear distortion and cannot be represented by a linear transformation.

The linear distortion includes scaling distortion in which the displacement amount increases at a constant rate along the radial direction from the center. The scaling distortion is a value obtained by dividing the amount of misalignment from the design value at a distance X from the center of the substrates 211 and 213 by X, and is measured in units of ppm. The scaling distortion includes isotropic scaling distortion. The isotropic scaling distortion is distortion in which the X component and the Y component of a displacement vector from the design position are equal, i.e. the scaling in the X direction and the scaling in the Y direction are equal. On the other hand, anisotropic scaling distortion in which the X component and Y component of the displacement vector from the design position are different, i.e. distortion in which the scaling in the X direction and the scaling in the Y direction are different, is included in non-linear distortion.

In the present embodiment, the difference in the scaling distortion based on the design position of each structure of the two substrates 211 and 213 is included in the positional misalignment amount between the two substrates 211 and 213.

Furthermore, the linear distortion includes orthogonal distortion. The orthogonal distortion is distortion by which, when the X-axis and the Y-axis are set orthogonal to each other with the center of a substrate as the origin, a structure is displaced from the design position, in a direction parallel to the X-axis direction, by an amount that is greater the farther the structure is from the origin in the Y-axis direction. This displacement amount is equal in each of a plurality of regions that cross the Y-axis in a direction parallel to the X-axis, and the absolute value of the displacement amount is greater the farther away from the X-axis. Furthermore, in the orthogonal distortion, the direction of displacement in the positive Y-axis region and the direction of the displacement in the negative Y-axis region are opposite each other.

The stereoscopic distortion of the substrates 211 and 213 is displacement in a direction that is not the direction along the bonded surfaces of the substrates 211 and 213, i.e. a direction that intersects with the bonding surfaces. The stereoscopic distortion includes curving occurring in some or all of each substrate 211 and 213 due to bending of all or a portion of the substrates 211 and 213. Here, the bending of a substrate refers to the shape of the substrate 211 or 213 changing into a shape in which a point that is not present in a plane defined by three points on the substrate 211 or 213 is included on the surface of the substrate 211 or 213.

Furthermore, curving is distortion in which the surface of the substrate forms a curved surface, and includes warping of the substrates 211 and 213, for example. In the present embodiment, warping refers to stereoscopic distortion that remains in the substrates 211 and 213 in a state where the effect of gravity has been eliminated. Distortion of the substrates 211 and 213 due to both the effect of gravity and the warping is referred to as deflection. The warping of the substrates 211 and 213 includes global warping in which the entirety of the substrate 211 or 213 is curved with a constant curvature and local warping in which a portion of the substrate 211 or 213 is curved with a changing curvature.

Here, the scaling distortion is classified as initial scaling distortion, adhesion scaling distortion, or bonding process scaling distortion, depending on the cause of the distortion.

The initial scaling distortion is caused by factors such as the stress generated in the process of forming the alignment marks 218, the circuit regions 216, and the like on the substrates 211 and 213 and periodic rigidity change caused by the arrangement of the scribe lines 212, the circuit regions 216, and the like, and manifests from the stage before the bonding of the substrates 211 and 213 as a deviation from the design specifications of the substrates 211 and 213. Accordingly, the initial scaling distortion of the substrates 211 and 213 can be known from before the layering of the substrates 211 and 213 is started, and the control section 150 may acquire information concerning the initial scaling distortion from a pre-processing apparatus that manufactured the substrates 211 and 213, for example.

The adhesion scaling distortion corresponds to change in the scaling distortion caused by the bonding of the substrates 211 and 213 in which distortion such as warping has occurred or by adhesion of these substrates 211 and 213 to the substrate holder 220. In other words, when a substrate 210 in which warping has occurred is adhered to and held by the substrate holder 220, the substrate 210 deforms to match the shape of the holding surface of the substrate holder 220. Here, when the substrate 210 changes from a state including warping to a state matching the shape of the holding surface of the substrate holder 220, the amount of distortion of the substrate 210 changes compared to before the substrate 210 was held.

Therefore, the distortion amount changes relative to the design specifications of the circuit regions 216 on the surface of the substrate 210, compared to the state of the substrate 210 before being held. The change in the distortion amount of the substrate 210 differs according to the configurations of the structures such as the circuit regions 216 formed on the substrate 210, the processes for forming these structures, magnitude of the warping of the substrate 210 before being held, and the like. The magnitude of the adhesion scaling distortion can be calculated from the state of the distortion including the warping amounts, warped shapes, and the like of the substrates 211 and 213, by performing an investigation in advance of the correlation between the adhesion scaling distortion and the distortion occurring when the substrates 211 and 213 experience distortion such as warping.

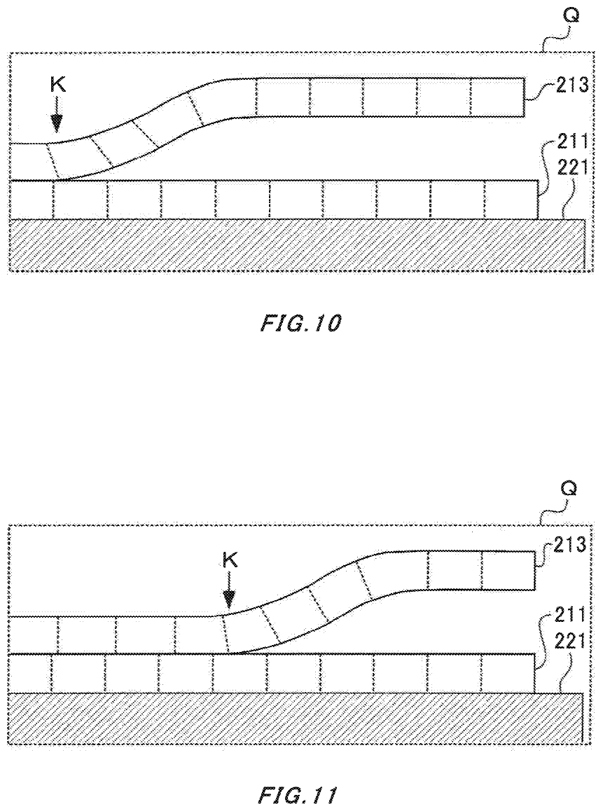

The bonding process scaling distortion is a newly occurring change in the scaling distortion caused by distortion that occurs in the substrate 211 or 213 during the bonding process. FIGS. 10, 11, and 12 are partial enlarged views showing the bonding process of the substrates 211 and 213 on the substrate holder 221 for the fixed side that has a flat holding surface. FIGS. 10, 11, and 12 show an enlarged view of a region Q that is near a boundary K between the contact region in which the substrates 211 and 213 contact each other and a non-contact region where the substrates 211 and 213 are separated from and not in contact with each other but will be bonded from this point, in the substrates 211 and 213 that are currently undergoing the bonding process by the bonding section 300.

As shown in FIG. 10, in the step where the surface area of the contact region between the two substrates 211 and 213 being bonded expands from the center to the outer periphery, the boundary K moves from the center of the substrates 211 and 213 toward the outer periphery. Near the boundary K, the substrate 213 that has been released from the holding by the substrate holder 223 stretches due to the air resistance occurring when air interposed between the substrate 213 and the substrate 211 is forced out. Specifically, at the boundary K, the substrate 213 stretches at the bottom surface side thereof in the drawing, relative to the surface of the substrate 213 in the center in the thickness direction, and the substrate 213 contracts at the top surface side thereof in the drawing.

In this way, as shown by the dotted lines in the drawing, the scaling distortion relative to the design specifications of the circuit regions 216 on the surface of the substrate 213 causes distortion that seems to make the substrate 213 expand relative to the substrate 211, at the outer end of the region of the substrate 213 bonded to the substrate 211. Therefore, as shown by the misalignment between the dotted lines in the drawing, positional misalignment caused by the difference in the stretching amount, i.e. the scaling distortion, of the substrate 213 occurs between the substrate 211 on the bottom side held by the substrate holder 221 and the substrate 213 on the top side that has been released from the substrate holder 223.

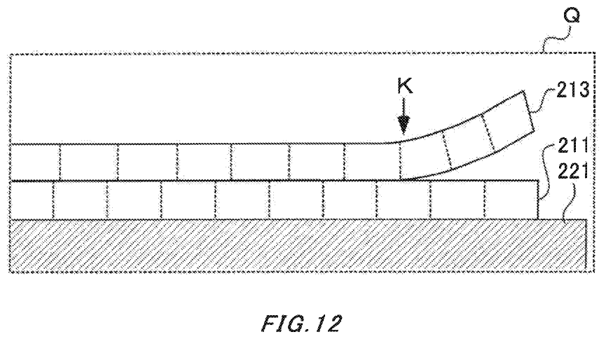

Furthermore, as shown in FIG. 11, when the substrates 211 and 213 contact each other and are bonded in the state described above, the scaling distortion caused by the expansion of the substrate 213 is fixed. Yet further, as shown in FIG. 12, the stretching amount of the substrate 213 fixed by the bonding accumulates as the boundary K moves toward the outer periphery of the substrates 211 and 213.

The amount of the bonding process scaling distortion such as described above can be calculated based on physical quantities such as the rigidity of the substrates 211 and 213 to be bonded, the viscosity of the atmosphere sandwiched between the substrates 211 and 213, and the adhesive force between the substrates 211 and 213. Furthermore, the misalignment amount caused by the bonding of substrates manufactured in the same lot as the substrates 211 and 213 to be bonded may be measured and recorded in advance, and the control section 150 may acquire the recorded measurement values as the information concerning the bonding process scaling distortion occurring when the substrates 211 and 213 of this lot are bonded. In the present embodiment, the bonding process is the process that occurs from when portions of the substrates 211 and 213 contact each other to when the expansion of the contact region has ended.

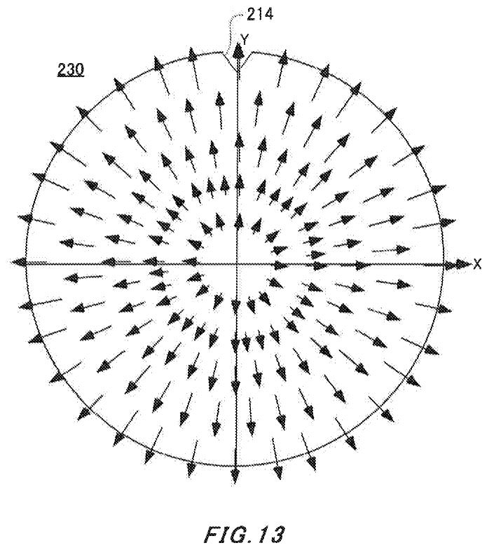

FIG. 13 is a schematic view of the positional misalignment in the multilayer substrate 230 caused by the scaling distortion occurring when the substrate holder 221 used for the fixed side has a flat holding surface. The arrows in the drawing are vectors indicating the positional misalignment of the substrate 213 on the releasing side with the substrate 211 on the fixed side used as a reference, the directions of these arrows indicate the direction of the positional misalignment, and the lengths of these arrows indicate the magnitude of the positional misalignment. The misalignment shown in the drawing has a misalignment amount that gradually increasing radially from the center point of the multilayer substrate 230 in a surface direction. The scaling distortion shown in the drawing includes the initial scaling distortion and the adhesion scaling distortion that occur before the bonding of the substrates 211 and 213 and also the bonding process scaling distortion that occurs during the bonding process of the substrates 211 and 213.

When the substrates 211 and 213 are bonded, one of the substrates, e.g. the substrate 211, is in the held state and the other substrate 213 is released. Therefore, at the timing when the substrates 211 and 213 are bonded, the shape of the substrate 211 that is held is fixed, but the substrate 213 that is released is bonded while distorting. Accordingly, it is not necessary to consider the bonding process scaling distortion for the substrate 211 that is bonded while being fixed, and it is preferable to consider the bonding process scaling distortion of the substrate 213 being released.

If the fixed substrate 211 is held in a distorted state due to the shape of the substrate holder 221 or the like, both the bonding process scaling distortion and the adhesion scaling distortion with respect to the released substrate 213 are preferably considered, and furthermore, distortion such as the adhesion scaling distortion caused by the substrate 213 conforming to the shape of the distorted substrate 211 is also preferably considered.

In this way, the difference in the final scaling distortion after the bonding of the substrate 211 and the substrate 213 is formed by adding, to the difference of the initial scaling distortion that the substrates 211 and 213 originally have, the difference of the adhesion scaling distortion occurring when the substrates 211 and 213 are held by the substrate holders 221 and 223 or the like and the bonding process scaling distortion of the substrate 213 released from the holding during the bonding process.

In the manner described above, the positional misalignment occurring in the multilayer substrate 230 formed by layering the substrates 211 and 213 is related to the magnitudes of the difference in the initial scaling distortion, the difference in the adhesion scaling distortion, and the difference in the bonding process scaling distortion. Furthermore, the scaling distortion occurring in the substrates 211 and 213 is related to the distortion such as warping in these substrates.

Furthermore, the difference in the initial scaling distortion, the difference in the adhesion scaling distortion, and the difference in the bonding process scaling distortion can be estimated by performing measurements, calculations, or the like before the bonding, in the manner described above. Accordingly, countermeasures for correcting the final difference can be taken in advance based on this final scaling distortion after the bonding estimated for the substrates 211 and 213 to be bonded.

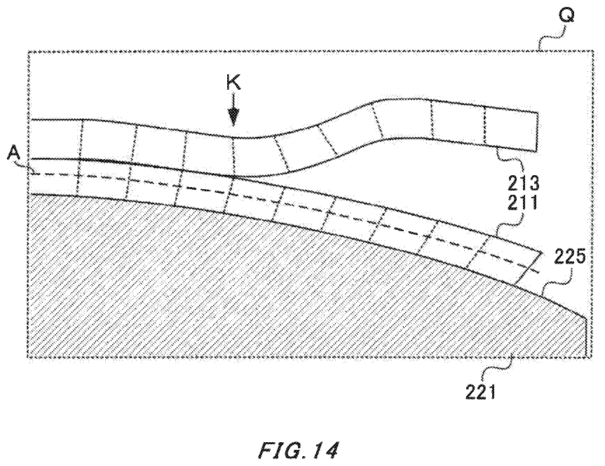

One example of such a countermeasure to be considered is selecting a substrate holder 221 having a holding surface with a curvature that can correct the difference in the final scaling distortion, from among a plurality of substrate holders 221 for the fixed side. FIG. 14 is a partial enlarged view of the bonding process of the substrates 211 and 213 on a substrate holder 221, in a case where the scaling distortion caused by air resistance has been corrected using the substrate holder 221 for the fixing side that has a curved holding surface.

As shown in FIG. 14, the holding surface 225 of the substrate holder 221 for the fixed side is curved. When the substrate 211 is adhered to the holding surface 225 having this shape, in a state where the substrate 211 is curved, the shape of the substrate 211 changes such that front surface of the substrate 211 that is the top surface in the drawing expands in the surface direction from the center toward the outer periphery more than the center portion A in the thickness direction of the substrate 213 shown by the dashed line. Furthermore, at the back surface that is the bottom surface of the substrate 211 in the drawing, the shape of the substrate 211 changes such that the surface of the substrate 211 contracts in the surface direction from the center toward the outer periphery.

By holding the substrate 211 with the substrate holder 221 in this manner, the surface of the substrate 211 on the top side in the drawing expands more than in a state where the substrate 211 is flat. Due to such a change in the shape, it is possible to correct the difference in the final scaling distortion with respect to the other substrate 213, i.e. the positional misalignment caused by this difference. Furthermore, by preparing a plurality of substrate holders 221 having curved holding surfaces 225 with different curvatures and selecting the substrate holder 221 whose holding surface 225 has a curvature that causes the positional misalignment amount caused by the difference of the final scaling distortion to be less than or equal to a predetermined threshold value, it is possible to adjust this correction amount.

In the embodiment shown in FIG. 4 or FIG. 14, the holding surface 225 of the substrate holder 221 has a shape that protrudes in the center. Instead, by preparing a substrate holder 221 that is depressed in the center portion relative to the outer periphery of the holding surface 225 and holding the substrate 211 with this substrate holder 221, it is possible to reduce the scaling of the bonding surface of the substrate 211 and to adjust the positional misalignment relative to the design specification of the circuit regions 216 formed on the bonding surface.

The above references FIGS. 10 to 13 to describe the scaling distortion, particularly the bonding process scaling distortion, within the linear distortion included in the planar distortion occurring in the substrates 211 and 213 to be bonded. Furthermore, FIG. 14 is referenced to describe an example of a countermeasure for, based on the difference in the final scaling distortion after bonding that is estimated for the substrates 211 and 213 to be bonded, correcting this difference.

The following describes distortion caused by anisotropy caused by the crystal orientation, i.e. crystal anisotropy, of the substrates 211 and 213 within the non-linear distortion included in the planar distortion occurring in the substrates 211 and 213 to be bonded.

FIG. 15 is a schematic view of a relationship between the crystal anisotropy and Young's modulus in a silicon single-crystal substrate 208. As shown in FIG. 15, in the silicon single-crystal substrate 208 having the (100) surface as the front surface, in an X-Y coordinate system where the direction of the notch 214 relative to the center is 0°, Young' modulus has a high value of 169 GPa at the 0° direction and the 90° direction, and Young's modulus has a low value of 130 GPa at the 45°direction. Therefore, in the substrate 210 manufactured using the silicon single-crystal substrate 208, there is an uneven bending rigidity distribution in the circumferential direction of the substrate 210. In other words, the bending rigidity of the substrate 210 differs according to the progression direction at the time when the bonding wave progresses from the center of the substrate 210 toward the outer periphery. The bending rigidity indicates the ease with which the substrate 210 deforms in response to a bending force, and may be the elastic modulus.

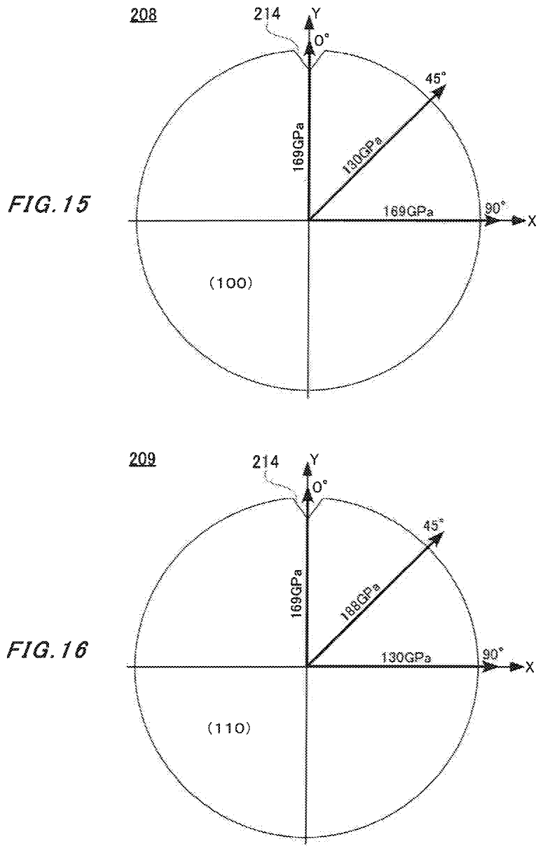

FIG. 16 is a schematic view of a relationship between the crystal anisotropy and Young's modulus in a silicon single-crystal substrate 209. As shown in FIG. 16, in the silicon single-crystal substrate 209 having the (110) surface as the front surface, in an X-Y coordinate system where the direction of the notch 214 relative to the center is 0°, Young' modulus has a highest value of 188 GPa at the 45° direction, and Young's modulus has the next highest value of 169 GPa at the 0° direction. Furthermore, Young's modulus has the lowest value of 130 GPa at the 90° direction. Therefore, in the substrate 210 manufactured using the silicon single-crystal substrate 209, there is a complicated and uneven bending rigidity distribution in the circumferential direction of the substrate 210.

In this way, in the substrate 210 formed using either of the silicon single-crystal substrates 208 and 209 having different crystal anisotropy, there is an uneven bending rigidity distribution in the circumferential direction thereof. The magnitude of the distortion that occurs in the bonding process described with reference to FIGS. 10 to 12 differs between the regions with different bending rigidities, according the magnitude of the bending rigidity. Specifically, the magnitude of the distortion of a region with low rigidity is less than the magnitude of the distortion in a region with high rigidity. Therefore, in the multilayer substrate 230 manufactured by layering the substrates 211 and 213, uneven positional alignment of the circuit regions 216 occurs in the circumferential direction of the multilayer substrate 230.

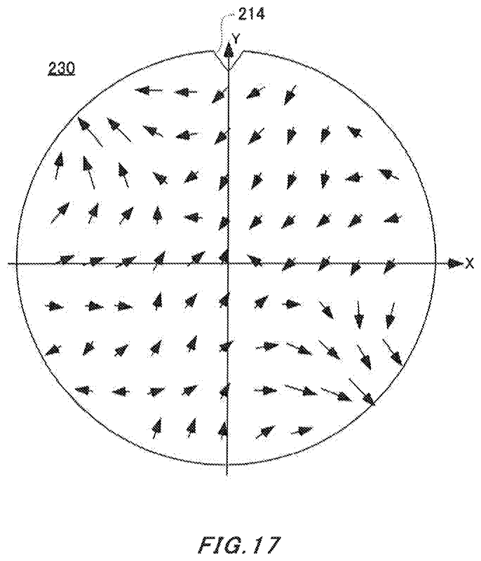

FIG. 17 is a schematic view of positional misalignment in the multilayer substrate 230 caused by non-linear distortion occurring when the substrate 210 on the releasing side is partially curved. The positional misalignment caused by the non-linear distortion shown in FIG. 17 does not include positional misalignment due to the scaling distortion caused by air resistance shown in FIG. 13.

As shown in FIG. 17, the positional misalignment caused by the non-linear distortion in the multilayer substrate 230 is significant in a second quadrant and a fourth quadrant, but there is no regular distribution of the positional misalignment amount along the radial direction from the center of the multilayer substrate 230. With reference to FIG. 17, it is understood that the positional misalignment caused by the non-linear distortion cannot be expressed by a linear transformation of the position displaced relative to the designed position of each structure of the substrates 211 and 213.

The non-linear distortion occurs due to a wide variety of factors interacting with each other, but the main factors are the crystal anisotropy in the silicon single-crystal substrate 208 or 209 described with reference to FIGS. 15 and 16 and the manufacturing process of the substrate 210. As described with reference to FIG. 2, in the manufacturing process of the substrate 210, a plurality of structures are formed on the substrate 210. For example, a plurality of circuit regions 216, a scribe line 212, and a plurality of alignment marks 218 are formed as the structures on the substrate 210. Each of the plurality of circuit regions 216 has a wire, a protective film, and the like formed thereon as structures using photolithography techniques or the like, as well as having arranged thereon a connecting section such as pads or bumps to serve as a connection terminal when the substrate 210 is electrically connected to another substrate 210, a lead frame, or the like. The form and arrangement of these structures, i.e. the configuration of these structures, affects the in-plane rigidity distribution and in-plane stress distribution of the substrate 210, and causes partial curving of the substrate 210 when the rigidity distribution or in-plane stress distribution becomes uneven.

The configuration of these structures may differ for each substrate 210, or may differ for each type of substrate 210 such as a logic wafer, a CIS wafer, and a memory wafer. Furthermore, even if the manufacturing process is the same, it is conceivable that the configuration of the structures will differ significantly due to the manufacturing apparatuses, and therefore the configuration of these structures may differ for each substrate 210 manufacturing lot. In this way, the configuration of a plurality of structures formed on a substrate 210 can differ for each substrate 210, each type of substrate 210, each substrate 210 manufacturing lot, and each substrate 210 manufacturing process. Due to this, the in-plane rigidity distribution of the substrate 210 differs in the same manner. Accordingly, the curved state of each substrate 210 caused by the manufacturing process and bonding process differs in the same manner.

When a pair of substrates 210 are bonded and a substrate 210 that is partially curved to have a shape recessed from the other substrate 210 being bonded is on the releasing side, there is a greater distance between this substrate 210 and the other substrate 210 during the bonding at a location where the curving occurs in the substrate 210 than at a location where curving does not occur. Therefore, at the location where the curving occurs, the progression of the bonding wave is slower than at the location where the curving does not occur, a wrinkle occurs at the location where the curving occurred in the substrate 210 on the releasing side, and this causes non-linear distortion in the bonded multilayer substrate 230. In other words, there is a correlation between the partial curving and the non-linear distortion, and at a location where there is a large amount of curving in the substrate 210 on the releasing side before the bonding, a large amount of non-linear distortion occurs in the multilayer substrate 230 after the bonding. It should be noted that this cause and effect does not fall under a case where there is no distortion other than the distortion caused by partial curving. On the other hand, even in a case where a substrate 210 to be bonded is partially curved, it is possible that the non-linear distortion that can occur due to the partial curving is cancelled out by the distortion caused by the crystal anisotropy, for example.

When partial curving occurs from before the bonding in the substrate 210 that is on the fixed side during the bonding among the pair of substrates 211 and 213, the entire surface on this one side is adhered to the substrate holder 220 or the like and kept in a fixed state, and therefore non-linear distortion due to the curvature of this substrate 210 does not occur, and non-linear positional alignment caused by the curvature of the fixed substrate does not occur between the substrates 211 and 213 after the bonding. It should be noted that, although adhesion scaling distortion or the like might occur in the substrate 210 on the fixed side, such distortion is small compared to the distortion occurring in the substrate 210 on the releasing side, and since this distortion has almost no effect it may be ignored. On the other hand, when partial curving occurs in the substrate 210 on the releasing side during the bonding, positional misalignment caused by non-linear distortion occurs between the bonded pair of substrates 211 and 213, for the reason described above. Therefore, the control section 150 acquires information relating to the curving of each of the substrates 211 and 213 before the bonding and determines which of the substrates 211 and 213 is to be on the releasing side based on the information concerning the curving of each of the substrates 211 and 213, and it is possible to restrict the positional misalignment caused by the non-linear distortion if the bonding section 300 performs the bonding based on this determination. The information concerning curving is included in the information concerning distortion.

The information concerning curving of the substrates 211 and 213 includes information obtained by measuring curving of the substrates 211 and 213 and information concerning the causes of the curving in the substrates 211 and 213. The information obtained by measuring curving of the substrates 211 and 213 includes information concerning curving characteristics such as a warping magnitude, warping direction, warped portion, warping amplitude, deflection magnitude, deflection direction, deflection amplitude, deflected portion, internal stress, and stress distribution of the substrates 211 and 213. The information concerning the causes of the curving of the substrates 211 and 213 includes the manufacturing processes of the substrates 211 and 213, the types of the substrates 211 and 213, and the configurations of the structures formed on the substrates 211 and 213. The control section 150 may acquire the information concerning curving of the substrates 211 and 213 from a pre-processing apparatus such as an exposure apparatus, deposition apparatus, or the like used for processes performed before the processing by the multilayer substrate manufacturing apparatus 100. Furthermore, the multilayer substrate manufacturing apparatus 100 may acquire the information concerning curving of the substrates 211 and 213 from the pre-aligner 500, for example, that is used for a process performed before the processing by the bonding section 300. The control section 150 outputs the information determined based on the acquired information to at least one of the transporting section 140, the pre-aligner 500, and the bonding section 300.

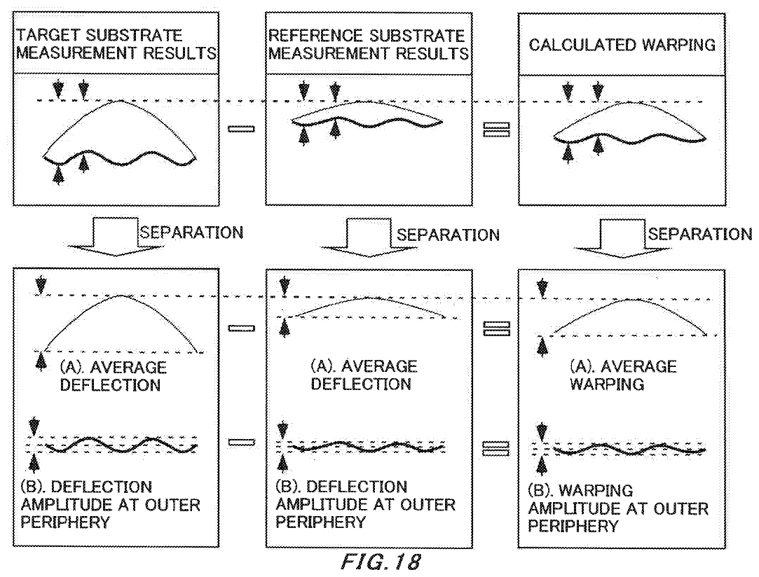

In the present embodiment, the curving of the substrate 211 and 213 is actually measured by the pre-processing apparatus, as an example. FIG. 18 is a diagram for describing the deflection measurement and warping calculation method. In the method of FIG. 18, first, the deflection of the substrate 211 or 213 serving as a target substrate is measured. Specifically, while the center of the back surface of the substrate 211 or 213 in the surface direction is supported and the substrate 211 or 213 is rotated around this center under the effects of gravity, a non-contact distance meter such as a microscope is used to monitor the front surface or back surface of the substrate 211 or 213, and the position of this front surface or back surface is measured based on the distribution of the distance information acquired from an automatic focusing function of the optical system of the microscope.

In this way, it is possible to measure the deflection amount that includes the magnitude and orientation of the deflection of the substrate 211 or 213 under the effect of gravity. The deflection amount of the substrate 211 or 213 is obtained from the displacement of the position of the front surface or back surface in the thickness direction of the substrate 211 or 213 when the supported center of this substrate 211 or 213 is used as a reference. Next, the control section 150 acquires the deflection amount information of the substrate 211 or 213, and divides this into a linear component and a non-linear component along a radial direction from the substrate center. In FIG. 18, the linear portion of the deflection amount of the substrate 211 or 213 is shown parabolically as an average deflection (A) and the non-linear component is shown with a wave as an amplitude (B) of the deflection at the outer periphery.

Next, the deflection of bare silicon serving as a reference substrate is measured. Bare silicon is the substrate 211 or 213 without structures formed thereon, and can be treated as a substrate 211 or 213 in which warping does not occur. The deflection amount of the bare silicon is measured using the same measurement conditions as used for the substrate 211 or 213. The control section 150 then acquires the information concerning the deflection amount of the bare silicon, and divides this into a linear component ((A) in FIG. 18) and a non-linear component ((B) in FIG. 18) along the radial direction from the center of the bare silicon.

The amplitude of the deflection at the outer periphery of the bare silicon is then subtracted from the amplitude of the deflection at the outer periphery of the substrate 211 or 213. In this way, it is possible to calculate the non-linear component of the warping amount of the substrate 211 or 213, which can be treated as a measurement value that is not under the effect of gravity. In FIG. 18, the non-linear portion of the warping amount of the substrate 211 or 213 is shown with a wave as the amplitude (B) of the warping at the outer periphery, and this corresponds to the local warping described above. The reason that it is possible to calculate the warping amount as the deformation amount measured while not under the effect of gravity using this method is that the deformation amount due to its own weight, which is included in the deflection amount that is the deflection amount measured under the effect of gravity, is substantially removed due to the subtraction described above.

By subtracting the average deflection of the bare silicon from the average deflection of the substrate 211 or 213, it is possible to calculate the linear component of the warping of the substrate 211 or 213, which can be treated as a measurement value not affected by gravity, and this linear component corresponds to the global warping described above. In FIG. 18, the linear component of the warping amount of the substrate 211 or 213 is shown parabolically as the average warping (A).

Finally, the situation occurring when bonding is performed using the substrate 211 or 213 as the substrate on the releasing side is reflected. Specifically, by converting the amplitude of the warping at the outer periphery of the substrate 211 or 213 in consideration of the direction of gravity and the orientation when the front surface of the substrate 211 or 213 faces downward, a predicted value is calculated for the amplitude of the warping at the outer periphery of the substrate 211 or 213 in a case where it is assumed that the center of the surface of the substrate 211 or 213 in the surface direction is supported and measured in the manner described above.

The control section 150 determines which of the substrates 211 and 213 is to be the substrate on the releasing side, based on the amplitude of the warping at the outer periphery of each of the substrates 211 and 213, i.e. the widths of the mountains and valleys at the outer periphery deformed into a wave shape, when it is assumed that the substrate 211 or 213 is used as the substrate on the releasing side, which is the information concerning the curving of the substrates 211 and 213 calculated in the manner described above. For example, the control section 150 may compare the magnitudes of the maximum values of the amplitudes of the warping at the outer peripheries and determine that the substrate with the larger maximum value is to be on the fixed side, or may compare the magnitudes of the average values of the amplitudes of the warping at the outer peripheries and determine that the substrate with the larger average value is to be on the fixed side. Furthermore, instead of making such a comparison, characteristics of the curving of each substrate may be judged from the information concerning the warping amplitude at the outer periphery of each of the substrates 211 and 213, to determine whether the substrate 211 or 213 is to be on the releasing side of the fixed side. It is obvious that if one of the substrates 211 and 213 has a warping amplitude at the outer periphery calculated to be 0, i.e. the one substrate 211 or 213 is found to not be partially curved, this one substrate 211 or 213 is determined to be on the releasing side.

In addition to or instead of the above judgment standard, the orientation and amount of the global warping may be used as another judgment standard for determining whether the substrate 211 or 213 is to be on the releasing side or the fixed side. In this case, as an example, the substrate in which the orientation of the global warping causes a shape that protrudes toward the other substrate to be bonded among the two substrates 211 and 213 may be set on the releasing side, and the substrate in which the orientation of the global warping causes a shape that is recessed from the other substrate to be bonded may be set on the fixed side.

Furthermore, among the two substrates 211 and 213, the substrate in which the shape of the local warping is steep may be set on the fixed side. The distortion amount that can occur during the bonding process in each of the two substrates 211 and 213 may be actually measured, calculated, or estimated, and the substrate 211 or 213 with a smaller distortion amount may be set to the releasing side. A distortion correction amount may be calculated in advance, and the substrate 211 or 213 having the smaller distortion correction amount when bonded may be set to the releasing side.

As another method for judging which of the substrates 211 and 213 is to be on the releasing side or the fixed side includes, when the substrate with the larger global warping amount is set on the releasing side, compared to a case where the substrate with the smaller amount of global warping is set on the releasing side, the scaling distortion occurring when the substrate is adhered to the upper stage 322, the scaling distortion occurring due to the shape of this substrate conforming to the shape of the other substrate during bonding, the scaling distortion caused by air resistance during the bonding, the scaling difference in the circumferential direction caused by rigidity corresponding to the crystal orientation, and the like become large, and for this reason the substrate with the larger amount of global warping may be set on the fixed side. In a case where the two substrates 211 and 213 both have a protruding shape or both have a recessed shape, the substrate with the larger warping amount is set on the fixed side and the substrate with the smaller warping amount is set on the releasing side. The measurement of the shapes of the substrates 211 and 213 may be performed using the warping measurement described above.

In a case where, among the two substrates 211 and 213, a substrate in which global warping occurs and a substrate in which local warping occurs are to be bonded, the substrate in which the local warping occurs, which is the substrate in which non-linear distortion is prone to occurring, may be set on the fixed side. In other words, among the two substrates 211 and 213, the substrate having the smaller amount of non-linear distortion already occurring before the bonding or non-linear distortion that can occur during the bonding may be set on the releasing side.

Among the two substrates 211 and 213, if it is assumed the side of one substrate having the surface on which a plurality of circuit regions 216 are formed would become a recessed shape, i.e. if this substrate would have a shape recessed from the other substrate being bonded thereto, when the pair of substrates 211 and 213 partially contact each other and the one substrate is released, there is a concern that the outer peripheral portions will contact each other before the regions between the contact portion and the outer peripheral portions do. Therefore, the substrate having the recessed shape with respect to the other substrate may be set on the fixed side.

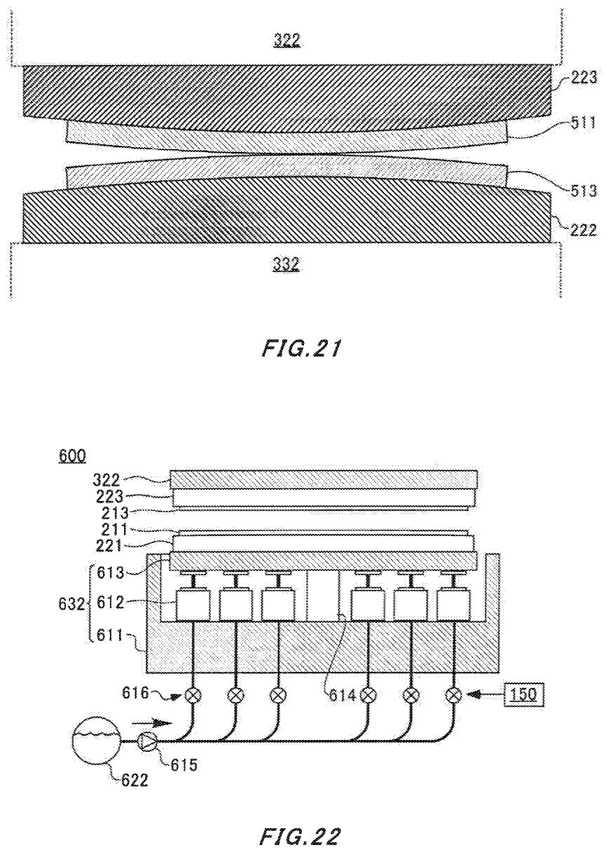

When the correction amount corresponding to the protrusion amount of a substrate holder having a holding surface with a curved shape in a manner to protrude more at the center portion than at the outer peripheral portion exceeds a maximum value capable of being corrected by a distortion correction mechanism using an actuator described further below in FIGS. 22 to 24, for example, the distortion cannot be corrected. Therefore, among the two substrates 211 and 213, the substrate having the larger necessary distortion correction amount, i.e. the substrate whose correction amount has a high possibility of exceeding the maximum value that can be corrected by the distortion correcting mechanism, may be set on the fixed side. In this case, among the two substrates 211 and 213, in a case where the initial scaling distortion of one substrate is X ppm and the initial scaling distortion of the other substrate is Y ppm, the substrate having the larger distortion correction amount may be determined by making a comparison between the distortion correction amount {Y−[X+(scaling distortion caused by air resistance)]} that is the difference in the scaling distortion after bonding when the one substrate is set on the releasing side and the distortion correction amount {X−[Y+(scaling distortion caused by air resistance)]} that is the difference in the scaling distortion after bonding when the other substrate is set on the releasing side.

A greater amount of curving, i.e. a greater curvature, results in a greater magnitude of the distortion occurring during the bonding process. In this case, among the two substrates 211 and 213, the substrate having the larger amount of curving may be set on the fixed side. Furthermore, in a case where the pair of substrates 211 and 213 to be bonded are both flat substrates that do not curve in the state prior to the bonding, it is possible that the scaling distortion caused by air resistance will change according to the difference in the rigidity distributions between the pair of substrates 211 and 213. In such a case, the substrate with the larger amount of scaling distortion caused by air resistance when on the releasing side may be set on the fixed side.

In a case where the one of the substrates 211 and 213 in the pair to be bonded is a CIS wafer including a plurality of pixels and the other is a logic wafer or memory wafer, the CIS wafer may be set on the releasing side. The thinking common to these judgment methods is that the substrate having the larger amount of distortion occurring during the bonding process should be on the fixed side. In this case, it may be conceivable to set the substrate for which distortion correction is possible by any distortion correcting means to be on the releasing side.

As described above, the distortion of the substrates 211 and 213 can differ for each substrate 211 and 213, each type of substrate 211 and 213, each manufacturing lot of the substrates 211 and 213, and each manufacturing process of the substrates 211 and 213. Accordingly, the determination of which of the substrates 211 and 213 is to be on the fixed side or the releasing side may be performed for any of each bonding of the substrates 211 and 213, each type of substrate 211 and 213, each manufacturing lot of the substrates 211 and 213, and each manufacturing process of the substrates 211 and 213.

The main embodiments are described above using FIGS. 1 to 18. In the main embodiments, in a state where the substrates 211 and 213 are adhered to the substrate holders 221 and the like and forcefully flattened, the residual stress of the substrates 211 and 213 may be measured using Raman scattering or the like and this residual stress may be set as information concerning the distortion of the substrates. Furthermore, the distortion of the substrates 211 and 213 may be measured in the pre-aligner 500.

In contrast, instead of measuring the distortion of the substrates 211 and 213, the control section 150 may acquire the information concerning the distortions of the substrates 211 and 213 analytically, and determine which of the substrates 211 and 213 are to be on the releasing side or the fixed side. In this case, the orientation and magnitude of the distortion occurring in the substrates 211 and 213, the shapes of the substrates 211 and 213, and the like may be estimated based on information concerning the manufacturing processes of the substrates 211 and 213, the configurations and materials of the structures such as the circuit regions 216 formed on the substrates 211 and 213, the types of the substrates 211 and 213, and the stress distributions of the substrates 211 and 213. In this case, the final scaling distortion and final non-linear distortion after bonding are calculated in the manner described above, and a comprehensive judgment is made based on these distortions to determine which of the substrates 211 and 213 is to be on the releasing side or the fixed side. Furthermore, information concerning the manufacturing processes for the substrates 211 and 213 generated in the process of forming the structures described above, i.e. chemical processing such as etching or a thermal history that accompanies deposition or the like, may be used as information concerning the causes of warping and the distortion occurring in the substrates 211 and 213 may be estimated based on this information.

When estimating the distortion occurring in the substrates 211 and 213, reference may also be made to peripheral information such as the surface structure of the substrates 211 and 213, the thickness of the thin film layered on the substrate 210, and trends, variations, deposition procedures, conditions, or the like of a deposition apparatus such as a CVD apparatus used for the film deposition, which could all be causes of distortion in the substrates 211 and 213. This peripheral information may be measured in advance with the purpose of estimating the distortion.

Furthermore, when estimating the distortion of the substrates 211 and 213 such as described above, past data or the like of the processing of equivalent substrates may be referenced, or an experiment of the process imagined to be performed on the substrate equivalent to the substrates 211 and 213 to be bonded may be conducted and data may be prepared in advance for a combination of the relationship between the warping amount included in the distortion and the scaling distortion, the relationship between the difference in the warping amount and the difference in the scaling distortion between the substrates, or the warping amount at which the difference in the scaling distortion between the substrates, i.e. the positional misalignment amount, becomes less than or equal to the predetermined threshold value. Yet further, data may be prepared by analytically obtaining the warping amount using a finite element method or the like, based on the deposition structures and deposition conditions of the substrates 211 and 213 to be bonded.

The measurement of the distortion amount for the substrates 211 and 213 may be performed outside the multilayer substrate manufacturing apparatus 100, or an apparatus that measures the distortion of the substrates 211 and 213 may be incorporated within the multilayer substrate manufacturing apparatus 100 or within a system that includes the multilayer substrate manufacturing apparatus 100. Furthermore, internal and external measurement apparatuses may both be used to increase the measured characteristics.

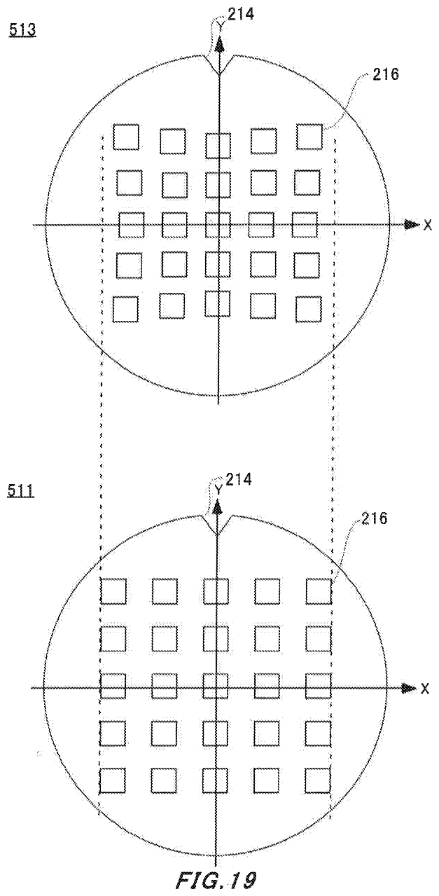

FIG. 19 is a schematic view of substrates 511 and 513 having a plurality of circuit regions 216 formed on the surfaces thereof. The arrangement of the plurality of circuit regions 216 is corrected in advance, such that the amount of positional misalignment in the multilayer substrate 230 due to the scaling distortion caused by air resistance that can occur during bonding and the non-linear distortion caused by crystal anisotropy becomes less than or equal to a predetermined threshold value. Here, at a stage at least before the substrates are transported to the bonding section 300, the control section 150 tentatively determines the substrate 513 to be on the releasing side and tentatively determines the substrate 511 to be on the fixed side, based on the types and manufacturing processes of the substrates 511 and 513, for example. The substrates 511 and 513 are each formed from the silicon single-crystal substrate 208 described using FIG. 15.

In the embodiment described above, the method for correcting in advance the scaling distortion caused by air resistance includes selecting a substrate holder with a curved holding surface 225 as the substrate holder 221 for the fixed side. However, the machining, handling, and the like of the substrate holders 221 and 223 or the upper stage 322 and lower stage 332 are easier if these components have flat holding surfaces. Therefore, in the present embodiment, instead of the correction method using the substrate holder 221 with the curved holding surface 225 for the fixed side, the arrangement of the plurality of circuit regions 216 formed on the surface of the substrate 513 tentatively determined to be on the releasing side is formed in a manner to be corrected in advance, thereby causing the positional misalignment in the multilayer substrate 230 due to the scaling distortion caused by the air resistance that can occur during the bonding and the non-linear distortion caused by the crystal anisotropy to be less than or equal to the predetermined threshold value. A substrate holder having a curved holding surface 227 for preventing a void is selected as the substrate holder 223 for the releasing side.

The substrate 511 tentatively determined to be on the fixed side is kept in a fixed state during the bonding, and therefore scaling distortion caused by air resistance and non-linear distortion caused by the crystal anisotropy are not expected to occur in the substrate 511. Therefore, in a case where a plurality of circuit regions 216 are formed on the entire substrate 511 by repeatedly exposing the substrate 511 while using the same mask, the plurality of circuit regions are formed at equal intervals across the entire substrate 511 without correcting the shot map.

On the other hand, the substrate 513 tentatively determined to be on the releasing side is expected to experience scaling distortion caused by air resistance and non-linear distortion caused by the crystal anisotropy during the bonding. Therefore, in a case where a plurality of circuit regions 216 are formed on the entire substrate 513 by repeatedly exposing the substrate 513 while using the same mask, the shot map is corrected such that the amount of positional misalignment due to the scaling distortion caused by air resistance and the non-linear distortion caused by crystal anisotropy becomes less than or equal to the predetermined threshold value. The intervals between the plurality of circuit regions 216 become gradually narrower across the entire substrate 513, from the center toward the outer periphery thereof, and the intervals in the radial direction and circumferential direction of the plurality of circuit regions 216 formed in region corresponding to the crystal orientation in the 45° direction are wider than the intervals in the 0° direction and 90° direction. Due to this, in a case where the substrate 513 tentatively determined to be on the releasing side is also determined to be on the releasing side according to the determination based on the information concerning the distortion of the substrates 511 and 513, which is performed later, even though the holding surface 225 of the substrate holder 221 for the fixed side is flat, it is possible to suppress the amount of positional misalignment in the multilayer substrate 230 due to the scaling distortion caused by air resistance that can occur during bonding and the non-linear distortion caused by the crystal anisotropy to be less than or equal to the predetermined threshold value. In a case where the distortion to be corrected is only scaling distortion, when correcting the shot map, the intervals of the plurality of circuit region 216 are constant from the center of the substrate 513 to the outer periphery, and the constant value of these intervals changes according to the magnitude of the scaling.

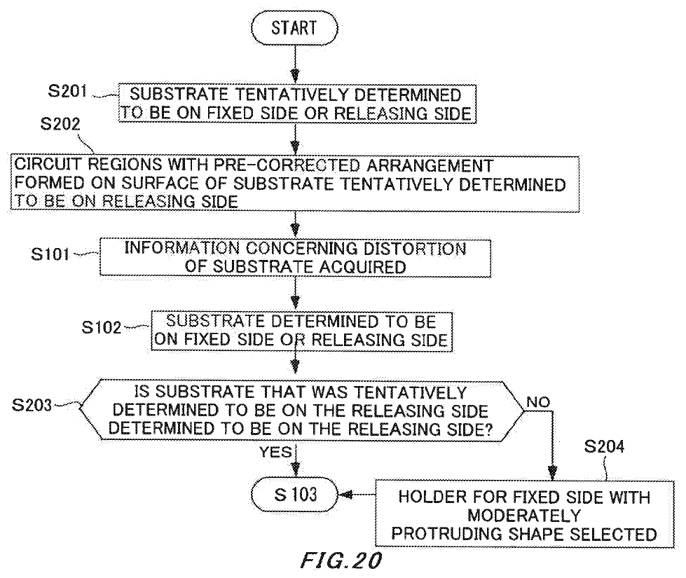

FIG. 20 is a flow chart showing a procedure for bonding the substrates 511 and 513 shown in FIG. 19 that have been corrected in advance. FIG. 21 is a diagram describing a method for correcting the scaling distortion caused by air resistance that can occur during bonding, in a case where, in a manner opposite the tentative determination described above, a determination is made to set the substrate 511 shown in FIG. 19 on the releasing side.

õ the substrate 511 is fixed to the lower stage 332 of the bonding section 300 and the substrate 513 is tentatively determined to be released from the upper stage 322 of the bonding section 300 (step S201), a plurality of circuit regions 216 are formed at uniform intervals on the surface of the substrate 511 by the pre-processing apparatus such as an exposure apparatus or deposition apparatus used in a process performed before a process by the multilayer substrate manufacturing apparatus 100, based on the tentative determination, and a plurality of circuit regions 216 with an arrangement that has been corrected as described above are formed on the surface of the substrate 513 (step S202). The tentative determination of step S201 may be performed by the pre-processing apparatus described above, or may be performed by the control section 150 of the multilayer substrate manufacturing apparatus 100 and output to the pre-processing apparatus. Furthermore, a determination may be made in advance for each of the substrates 511 and 513 to be bonded concerning whether this substrate is to be on the fixed side or the releasing side, and this information may be stored in a memory of the pre-processing apparatus.

Next, the information concerning the distortion of each of the substrates 511 and 513 to be bonded is acquired (step S101), and the determination is made concerning which of the substrates 511 and 513 is to be continued to be held by the lower stage 332 of the bonding section 300 or to be released from the hold of the upper stage 322 of the bonding section 300, based on the acquired information (step S102).

If it is determined at step S102 that the substrate 513, which was tentatively determined to be on the releasing side at step S201, is to be on the releasing side (step S203: YES), the process moves to step S103 and continues, such that, as described above, the substrate 513 is held by the substrate holder 223 for the releasing side having the curved holding surface 227, the substrate 511 is held by the substrate holder 221 for the fixed side having the flat holding surface 225, and the multilayer substrate 230 is formed by bonding the substrate 513 and substrate 511 using the bonding section 300.

On the other hand, if it is determined at step S102 that the substrate 513, which was tentatively determined to be on the releasing side at step S201, is to be on the fixed side (step S203: NO), a substrate holder that has a holding surface 225 with a curved shape whose curvature causes the positional misalignment amount due to the scaling distortion caused by air resistance and the non-linear distortion caused by the crystal anisotropy to become less than or equal to the predetermined threshold value is selected as the substrate holder 222 for the fixed side (step S204), and then the process proceeds to step S103 and continues, such that the substrate 511 is held by the substrate holder 223 for the releasing side having the curved holding surface 227, the substrate 513 is held by the substrate holder 222 for the fixed side having the curved holding surface 225, and the multilayer substrate 230 is formed by bonding the substrate 511 and the substrate 513 using the bonding section 300, as shown in FIG. 21. The distortion correction amount realized by using the substrate holder 222 for the fixed side selected at step S204 must cancel out the distortion correct portion of step S202 and cause the positional misalignment amount described above to become less than or equal to the predetermined threshold value, and therefore this distortion correction amount is approximately double the distortion correction amount of step S202, for example. When considering the difference caused by the initial scaling distortion between the substrates 511 and 513 as well, the distortion correction amount described above is slightly decreased or increased from this doubled value.

As described above, in the present embodiment, in a case where the substrate 513 that was tentatively determined to be on the releasing side is also determined to be on the releasing side by the determination based on the information relating to the distortion of the substrates 511 and 513, even though the holding surface 225 of the substrate holder 221 for the fixed side is flat, it is possible to suppress the positional misalignment in the multilayer substrate 230 due to the scaling distortion caused by air resistance that can occur during bonding and the non-linear distortion caused by the crystal anisotropy to be less than or equal to the predetermined threshold value. Furthermore, even in a case where the substrate 513 that was tentatively determined to be on the releasing side is determined to be on the fixed side by the determination based on the information relating to the distortion of the substrates 511 and 513, by selecting the substrate holder 222 having the curved holding surface 225 with the prescribed curvature for the fixed side, it is possible to suppress the positional misalignment in the multilayer substrate 230 due to the scaling distortion caused by air resistance that can occur during bonding and the non-linear distortion caused by the crystal anisotropy to be less than or equal to the predetermined threshold value.

FIGS. 22 to 24 show an embodiment different from the embodiment shown in FIG. 14, as a method for correcting the positional misalignment caused by the difference in the distortion occurring between the two substrates 211 and 213. In this other embodiment, the correction amount of the substrate 211 on the fixed side is adjusted by changing the surface shape of the lower stage 632 holding the substrate 211 on the fixed side, according to the magnitude of the scaling distortion caused by the air resistance of the substrate 213 on the releasing side.

FIG. 22 is a schematic cross-sectional view of a portion of the bonding section 600 according to another embodiment. The bonding section 600 has the same configuration as the bonding section 300 in the embodiment described above, aside from having a different configuration for the lower stage 332, and therefore redundant descriptions are omitted. The holding surfaces 225 and 227 of the respective substrate holders 221 and 223 may have any shapes.

The lower stage 632 of the bonding section 600 includes a base portion 611, a plurality of actuators 612, and an adhering section 613. The base portion 611 supports the adhering section 613 via the plurality of actuators 612.

The adhering section 613 includes an adhering mechanism such as a vacuum chuck or an electrostatic chuck, and forms the top surface of the lower stage 632. The adhering section 613 adheres and supports a substrate holder 221 transported thereto.

The plurality of actuators 612 are arranged along the bottom surface of the adhering section 613, below the adhering section 613. Furthermore, the plurality of actuators 612 are controlled by the control section 150 to be independently driven by a supply of operating fluid from an external pressure source 622, via a pump 615 and valves 616. In this way, the plurality of actuators 612 expand and contract with individually different expansion and contraction amounts in the thickness direction of the lower stage 632, i.e. the bonding direction of the substrates 211 and 213, to raise or lower the regions of the adhering section 613 connected thereto.

Furthermore, the plurality of actuators 612 are connected to the adhering section 613 via respective links. The center portion of the adhering section 613 is connected to the base portion 611 by the support column 614. When the plurality of actuators 612 operate, the surface of the adhering section 613 is deformed in the thickness direction in each of the regions where the plurality of actuators 612 are connected.

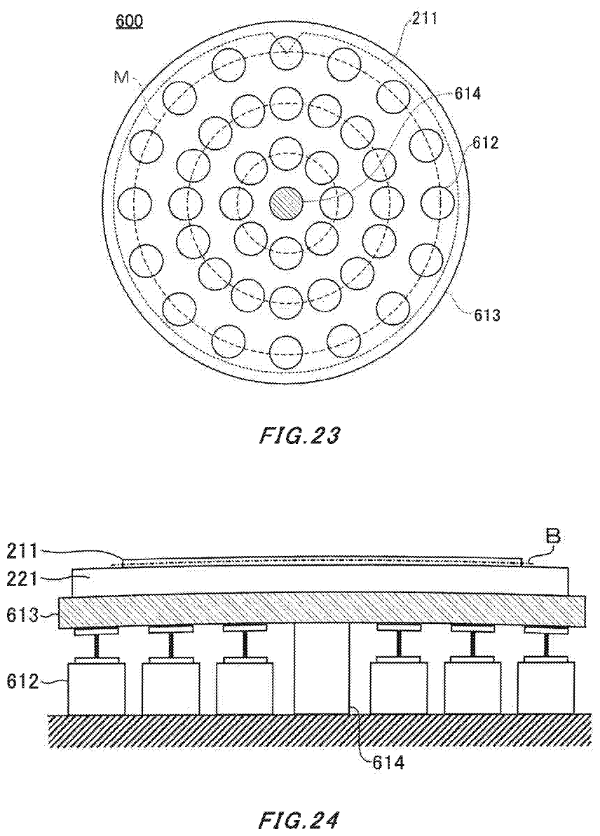

FIG. 23 is a schematic view of a layout of the actuators 612. The plurality of actuators 612 are arranged radially with the support column 614 as the center. The arrangement of the plurality of actuators 612 can also be thought of as concentric circles centered on the support column 614. The arrangement of the plurality of actuators 612 is not limited to the arrangement shown in the drawing, and the actuators 612 may be arranged in a grid shape, spiral shape, or the like, for example. In this way, it is possible to perform the correction by changing the shape of the substrate 211 to a concentric circle shape, a radial shape, a spiral shape, or the like.

FIG. 24 is a schematic view of the operation of a portion of the bonding section 600. As shown in the drawing, it is possible to change the shape of the adhering section 613 by causing the plurality of actuators 612 to expand and contract by independently opening and closing the valves 616. Accordingly, if the adhering section 613 has the substrate holder 221 adhered thereto and the substrate holder 221 is holding the substrate 211, it is possible to change the shape of the substrate holder 221 and the substrate 211 to be curved, by changing the shape of the adhering section 613.

As shown in FIG. 23, the plurality of actuators 612 can be treated as being arranged in concentric circles, i.e. in the circumferential direction of the lower stage 632. Accordingly, as shown by the dotted lines M in FIG. 23, by grouping the plurality of actuators 612 in each circumference and causing the driving amount to be greater closer to the peripheral edge, it is possible to cause the surface of the adhering section 613 to protrude at the center, thereby changing its shape to be a spherical surface, parabolic surface, cylindrical surface, or the like.

In this way, in the same manner as in the case where the substrate 211 is held by the curved substrate holder 221, it is possible to curve the substrate 211 by changing the shape thereof to conform to a spherical surface, parabolic surface, or the like. Accordingly, with the center position B in the thickness direction of the substrate 211 shown by the single-dot chain line in FIG. 24 as a border, the upper surface of the substrate 211 in the drawing is changed to have a shape whereby the surface of the substrate 211 expands in the surface direction. Furthermore, the bottom surface of the substrate 211 in the drawing is changed to have a shape whereby the surface contracts in the surface direction. Yet further, by controlling the expansion and contraction amounts of the plurality of actuators 612 individually, it is possible to curve the substrate 211 by changing the shape of the substrate 211 to non-linear shapes that include a plurality of uneven portions, in addition to the other shapes such as the cylindrical surface.

Accordingly, by causing the plurality of actuators 612 to operate individually via the control section 150, it is possible to partially or entirely adjust the misalignment of the plurality of circuit regions 216 on the surface of the substrates 211 relative to the design specifications. Furthermore, it is possible to adjust the amount by which the shape is changed, using the operating amounts of the plurality of actuators 612.

In the above example, the adhering section 613 has a shape that protrudes upward in the center. However, by increasing the operating amounts of the plurality of actuators 612 at the outer periphery of the adhering section 613 to create a depression in the center relative to the outer periphery of the adhering section 613, it is possible to reduce the scaling distortion of the plurality of circuit regions 216 on the surface of the substrate 211. In addition to this, in order to correct the scaling distortion of the substrates 211 and 213, other correction methods may be further introduced, such as thermal expansion or thermal contraction through temperature adjustment.

In a case where the distortions of the substrates 211 and 213 is corrected using temperature adjustment, it is preferable to cool the substrate on the side to be released from the holding during bonding or to heat the substrate on the fixed side. Furthermore, in a case where the correction is performed by heating one of the two substrates 211 and 213, when the heated substrate is held by the lower stage 332, the heat generated from the heated substrate rises up to toward the upper stage 322 and is transferred to the substrate held by the upper stage 322, thereby causing deformation of this substrate, and therefore it is preferable for the substrate that is heated to be held by the upper stage 322 and for the other substrate to be held by the lower stage 332. In other words, in this case, the other substrate held by the lower stage 332 is preferably the substrate for the releasing side.

The plurality of embodiments above are described having a configuration in which the shapes of the substrate holder for the fixed side and the shape of the substrate holder for the releasing side are different, so that when holding the substrates with the substrate holders, it is already determined which substrate is on the releasing side or the fixed side. In this case, in the multilayer substrate manufacturing apparatus, the transporting section receives this determination information, selectively extracts the substrate holder for the releasing side or for the fixed side from the holder cassette, and sequentially transports sets of a substrate and a substrate holder into the pre-aligner. However, in a case where the shapes of the substrate holders respectively on the releasing side and the fixed side are not different, the bonding section may receive this determination information and selectively hold the substrate holder holding the substrate with the upper stage or the lower stage.

The plurality of embodiments above are described having a configuration in which the control section of the multilayer substrate manufacturing apparatus determines one of the pair of substrates 211 and 213 to be on the fixed side and the other to be on the releasing side, but instead, this determination may be made by the pre-processing apparatus, for example, and the pre-processing apparatus may input the determined information to the control section of the multilayer substrate manufacturing apparatus.

The plurality of embodiments above are described having a configuration in which the determination about which of the substrates 211 and 213 in the pair is to be on the fixed side or the releasing side is made before the substrates are held by the stages of the bonding section. In this case, the stage on the side releasing the substrate is determined in advance, and the substrate determined to be on the releasing side is held by the stage determined for releasing in advance. In other words, in this case, the control section 150 determines the stages to respectively hold the substrates 211 and 213 in the pair according to the information concerning the distortion of each of the substrates 211 and 213 in the pair.

Instead, the determination of whether a substrate is to be kept held to be released may be made after this substrate is held by a stage. In this case, after this determination, the control section 150 may judge which stage is the stage holding the substrate determined to be released, and perform control to release the adhesion of this stage.

Alternatively, before the substrate is held by a stage, the control section 150 may determine at least one of the substrate to continue being held and the substrate to be released, judge which stage is holding the substrate to be released, and control this stage to release the substrate.

In the plurality of embodiments described above, during the bonding, the control section 150 may release the holds of the stages on both substrates 211 and 213 in the pair. In this case, a judgement of which of the substrates 211 and 213 in the pair is to be held by the upper stage or which is to be held by the lower stage may be made based on the information concerning the distortion.

Furthermore, in the process where the contact region between the substrates 211 and 213 expands, the control section 150 may release some or all of the hold on the substrate 211 by the substrate holder 221. When releasing the hold on the substrate 211 in the process where the contact region expands, the pulling force from the substrate 213 on the top side causes the substrate 211 on the bottom side to be lifted up from the substrate holder 221 and curve. Due to this, the shape of the surface of the substrate 211 on the bottom side changes by stretching, and therefore the difference with respect to the stretching amount of the surface of the substrate 213 on the top side decreases by this stretching amount of the substrate 211. Accordingly, the positional misalignment caused by different amounts of deformation between the two substrates 211 and 213 is suppressed.

By adjusting the holding force exerted by the substrate holder 221, it is possible to adjust the amount by which the substrate 211 is lifted up from the substrate holder 221, and therefore, when a difference occurs between the correction amount set in advance for the substrate holder 221 and the correction amount that is actually needed, it is possible to compensate for this difference by adjusting the holding force of the substrate holder 221. In a case where the substrate 211 is lifted up from the substrate holder 221 by adjusting the holding force of the substrate holder 221 in this manner, the control section 150 determines the substrate 211 to be the substrate on the fixed side.

In the plurality of embodiments described above, the adhesive force exerted by the stage on the fixed side may be adjusted, such that the substrate on the fixed side is held in a semi-fixed state. In this case, the substrate held in the semi-fixed state is pulled toward the other substrate due to the intermolecular force and pulled away from the substrate holder, and this is not included in the release of the substrate as described in the plurality of embodiments above.

Methods and apparatuses for manufacturing a multilayer substrate have been described above using a plurality of embodiments. In addition to or instead of these, there may be a multilayer substrate manufacturing system that manufactures a multilayer substrate by bonding a first substrate held by a first holding section and a second substrate held by a second holding section, by releasing the hold on at least one of the first substrate and the second substrate, and includes an acquiring section that acquires information concerning the distortion of each of the first substrate and the second substrate; a determining section that determines which of the first substrate and the second substrate is to be released from the hold or continued to be held, based on information concerning distortion occurring during a bonding process of the first substrate and the second substrate; and a bonding section that bonds the first substrate and the second substrate based on the determination.

In this case, the determining section may transmit, to a sorting device that sorts the substrates into transport containers housing the substrates to be bonded, a signal indicating sorting the substrates to be on the releasing side and substrates to be on the fixed side into separate transport containers or a signal indicating housing the substrates to be on the releasing side and substrates to be on the fixed side in an identifiable manner within a single transport container. Furthermore, the determining section may transmit to the multilayer substrate manufacturing apparatus 100, which is an example of the bonding section, at least one of a signal including information concerning the substrates to be on the releasing side and substrates to be on the fixed side, a signal indicating substrates to be held by the stage for releasing and substrates to be held by the stage for fixing, and a signal for controlling the stage holding the substrate on the releasing side to release the substrates during bonding.

In the embodiments above, examples are described in which, after portions of the substrates 211 and 213 have contacted each other, the substrates 211 and 213 are bonded by this contact region gradually expanding, but instead, the substrates 211 and 213 may be bonded by holding each of the substrates 211 and 213 with a flat holding portion and releasing the hold on one of these substrates. In this case, the determination of the substrate to be on the releasing side can be made using a method described in the above embodiments.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### LIST OF REFERENCE NUMERALS

100: multilayer substrate manufacturing apparatus, 110: case, 120, 130: substrate cassette, 140: transporting section, 150: control section, 208, 209: silicon single-crystal substrate, 210, 211, 213, 511, 513: substrate, 212: scribe line, 214: notch, 216: circuit region, 218: alignment mark, 220, 221, 222, 223: substrate holder, 225, 227: holding surface, 230: multilayer substrate, 300: bonding section, 310: frame, 312: floor plate, 316: ceiling plate, 322: upper stage, 324, 334: microscope, 326, 336: activation apparatus, 331: X-direction drive section, 332: lower stage, 333: Y-direction drive section, 338: raising and lowering drive section, 400: holder stocker, 500: pre-aligner, 600: bonding section, 611: base portion, 612: actuator, 613: adhering section, 614: support column, 615: pump, 616: valve, 622: pressure source, 632: lower stage

What is claimed is:

1. A substrate bonding method for bonding a first substrate held by a first holding section and a second substrate held by a second holding section, by releasing the hold on at least one of the first substrate and the second substrate, the substrate bonding method comprising:
determining which of the first substrate and the second substrate is to be released from the hold or continued to be held, based on information concerning distortion of at least one of the first substrate and the second substrate, wherein
the information concerning the distortion includes information concerning distortion occurring in a bonding process of the first substrate and the second substrate.

2. The substrate bonding method according to claim 1, wherein
the determining includes determining that a substrate, among the first substrate and the second substrate, in which the distortion occurring in the bonding process satisfies a prescribed condition is to be released.

3. The substrate bonding method according to claim 1, wherein
the information concerning the distortion includes information concerning a cause of the distortion,
the substrate bonding method further comprises estimating the distortion of each of the first substrate and the second substrate, based on information concerning a cause of the distortion, and
the determining includes making the determination based on the estimated distortion information.

4. The substrate bonding method according to claim 1, further comprising:
acquiring the information concerning the distortion, wherein
the acquiring includes measuring the distortion of each of the first substrate and the second substrate, and acquiring the measured distortion as the information.

5. The substrate bonding method according to claim 1, wherein
the information concerning the distortion includes information concerning at least one of a warping magnitude, warping direction, warped portion, warping amplitude, deflection magnitude, deflection direction, deflection amplitude, deflected portion, internal stress, and stress distribution of each of the first substrate and the second substrate.

6. The substrate bonding method according to claim 5, wherein
the information concerning the distortion includes information indicating a maximum value of the warping amplitude in each of the first substrate and the second substrate, and
the determining includes making the determination by comparing a magnitude of the maximum value of the first substrate to a magnitude of the maximum value of the second substrate, and determining that a substrate with the greater maximum value among the first substrate and the second substrate is to be continued to be held.

7. The substrate bonding method according to claim 5, wherein
the information concerning the distortion includes information indicating an average value of the warping amplitude in each of the first substrate and the second substrate, and
the determining includes comparing a magnitude of the average value of the first substrate to a magnitude of the average value of the second substrate, and determining that a substrate with the greater average value among the first substrate and the second substrate is to be continued to be held.

8. The substrate bonding method according to claim 1, wherein
the determining is performed for at least one of each bonding of the first substrate and the second substrate, each manufacturing lot of the first substrate, and each manufacturing lot of the second substrate.

9. A substrate bonding method comprising:
holding a first substrate with a first holding section;
holding a second substrate with a second holding section in a manner to face the first substrate; and
bonding the first substrate and the second substrate by releasing the hold on one of the first substrate and the second substrate, wherein
the bonding includes releasing the hold on a substrate, among the first substrate and the second substrate, in which distortion occurring in a bonding process satisfies a prescribed condition.

10. A substrate bonding method for bonding a first substrate held by a first holding section and a second substrate held by a second holding section, by releasing the hold on at least one of the first substrate and the second substrate, the substrate bonding method comprising:
determining which of the first substrate and the second substrate is to be held by the first holding section or by the second holding section, based on information concerning distortion occurring in a bonding process of the first substrate and the second substrate.

11. A substrate bonding method for bonding a first substrate held by a first holding section and a second substrate held by a second holding section, by releasing the hold on one of the first substrate and the second substrate, the substrate bonding method comprising:
determining which of the first substrate and the second substrate is to be released from the hold or continued to be held, based on information concerning distortion of at least one of the first substrate and the second substrate.

12. A substrate bonding method for bonding a first substrate held by a first holding section and a second substrate held by a second holding section, by releasing the hold on one of the first substrate and the second substrate, wherein
a substrate, among the first substrate and the second substrate, causing positional misalignment after bonding that is less than or equal to a threshold value is released from the hold.

13. A substrate bonding method comprising:
holding a first substrate with a first holding section;
holding a second substrate with a second holding section;
correcting positional misalignment between the first substrate and the second substrate; and
bonding the first substrate and the second substrate by releasing the hold on one of the first substrate and the second substrate, wherein
a substrate, among the first substrate and the second substrate, causing a correction amount for positional misalignment predicted for after the bonding with a magnitude capable of being corrected by the correcting is released from the hold.

14. A multilayer substrate manufacturing method comprising:
bonding a first substrate held by a first holding section and a second substrate held by a second holding section, by releasing the hold on at least one of the first substrate and the second substrate; and
determining which of the first substrate and the second substrate is to be released from the hold or continued to be held, based on information concerning distortion occurring in the bonding of the first substrate and the second substrate, wherein
the bonding includes releasing the hold on the substrate that was determined to be released in the determining.

15. A multilayer substrate manufacturing apparatus comprising:
a first holding section holding a first substrate; and
a second holding section holding a second substrate, wherein
the multilayer substrate manufacturing apparatus manufactures a multilayer substrate by bonding the first substrate and the second substrate, by releasing the hold on one of the first substrate and the second substrate, and
a substrate, among the first substrate and the second substrate, causing positional misalignment after bonding that is less than or equal to a threshold value is released from the hold.

16. A multilayer substrate manufacturing apparatus, comprising:
a first holding section that holds a first substrate; and
a second holding section that holds a second substrate in a manner to face the first substrate, wherein
the multilayer substrate manufacturing apparatus manufactures a multilayer substrate by bonding the first substrate and the second substrate, by releasing the hold on one of the first substrate and the second substrate, and
a substrate, among the first substrate and the second substrate, in which distortion occurring in a bonding process satisfies a prescribed condition is released from the hold.

17. A multilayer substrate manufacturing apparatus, comprising:
a first holding section that holds a first substrate;
a second holding section that holds a second substrate in a manner to face the first substrate; and
a correcting section that corrects positional misalignment between the first substrate and the second substrate, wherein
the multilayer substrate manufacturing apparatus manufactures a multilayer substrate by bonding the first substrate and the second substrate, by releasing the hold on one of the first substrate and the second substrate, and
a substrate, among the first substrate and the second substrate, causing a correction amount for positional misalignment predicted for after the bonding with a magnitude capable of being corrected by the correcting section is released from the hold.

18. A multilayer substrate manufacturing system comprising:
a bonding section that includes a first holding section holding a first substrate and a second holding section holding a second substrate, and bonds the first substrate and the second substrate by releasing the hold on one of the first substrate and the second substrate; and
a determining section that determines which of the first substrate and the second substrate is to be released from the hold or continued to be held, based on information concerning distortion occurring during a bonding process of the first substrate and the second substrate, wherein
the bonding section releases the hold on the substrate determined to be released by the determining section.
